(19) United States
(12) Patent Application Publication
(10) Pub. No.: US 2024/0387513 A1
(43) Pub. Date: Nov. 21, 2024

(54) SEMICONDUCTOR MODULE AND SEMICONDUCTOR UNIT

(71) Applicant: ROHM CO., LTD., Kyoto-shi (JP)

(72) Inventors: Isao TAKOBE, Kyoto-shi (JP); Kengo OHMORI, Kyoto-shi (JP)

(21) Appl. No.: 18/782,945

(22) Filed: Jul. 24, 2024

Related U.S. Application Data
(63) Continuation of application No. PCT/JP2022/047073, filed on Dec. 21, 2022.

(30) Foreign Application Priority Data
Jan. 28, 2022 (JP) 2022-012102

(51) Int. Cl. H01L 27/02; H01L 23/00; H01L 25/07; H01L 29/16; H01L 29/20; H01L 29/78

(52) U.S. Cl. CPC H01L 27/0288; H01L 24/40; H01L 24/48; H01L 29/16; H01L 29/2003; H01L 29/7808; H01L 24/32; H01L 24/73; H01L 25/072; H01L 27/0255; H01L 27/0266; H01L 2224/32225; H01L 2224/40137; H01L 2224/48225; H01L 2224/73263; H01L 2224/73265; H01L 2924/13091; H01L 2924/1815

(57) ABSTRACT

A semiconductor module comprises: a first chip that includes a main transistor including an electron transit layer which serves as a main drift layer; a second chip that includes at least a part of an active clamp circuit including a clamp transistor which operates on the basis of an increase in the drain-source voltage of the main transistor; a connection member that electrically connects the main transistor and the active clamp circuit; and a sealing resin that seals the first chip, the second chip, and the connection member. The clamp transistor includes a sub-drift layer composed of a material different from that of the main drift layer.

### CROSS-REFERENCE TO RELATED APPLICATIONS

This application is a continuation of, and claims the benefit of priority from International Application No. PCT/JP2022/047073, filed on Dec. 21, 2022, which claims the benefit of priority from Japanese Patent Application No. 2022-012102, filed on Jan. 28, 2022, the entire contents of each of which are incorporated herein by reference.

### BACKGROUND

### 1. Field

The present disclosure relates to a semiconductor module and a semiconductor unit.

### 2. Description of Related Art

A known discrete semiconductor device includes a power transistor as a main transistor (refer to, for example, Japanese Laid-Open Patent Publication No. 2018-82011).

### BRIEF DESCRIPTION OF DRAWINGS

FIG. 1 is a schematic plan view showing the internal structure of a semiconductor module in a first embodiment.

FIG. 2 is a cross-sectional view showing the semiconductor module taken along line F2-F2 in FIG. 1.

FIG. 3 is a cross-sectional view showing the semiconductor module taken along line F3-F3 in FIG. 1.

FIG. 4 is a back view of the semiconductor module shown in FIG. 1.

FIG. 5 is a cross-sectional view schematically showing the cross-sectional structure of a main transistor in the semiconductor module.

FIG. 6 is a cross-sectional view schematically showing the cross-sectional structure of a clamp transistor of an active clamp circuit in the semiconductor module.

FIG. 7 is a cross-sectional view schematically showing the cross-sectional structure of a clamp capacitor of the active clamp circuit in the semiconductor module.

FIG. 8 is a schematic cross-sectional view showing the cross-sectional structure of a pull-down resistor of the active clamp circuit in the semiconductor module.

FIG. 9 is a circuit diagram of the semiconductor module.

FIG. 10 is a graph showing changes in drain-source voltage and gate-source voltage of a main transistor and gate-source voltage of a clamp transistor.

FIG. 11 is a plan view schematically showing the internal structure of a semiconductor module in a second embodiment.

FIG. 12 is a plan view of the semiconductor module shown in FIG. 11.

FIG. 13 is a cross-sectional view of the semiconductor module taken along line F13-F13 in FIG. 11.

FIG. 14 is a plan view schematically showing the internal structure of a second chip in the semiconductor module.

FIG. 15 is a cross-sectional view taken along line F15-F15 in FIG. 14 schematically showing the cross-sectional structure of the second chip.

FIG. 16 is a plan view schematically showing the internal structure of a semiconductor module in a third embodiment.

FIG. 17 is a cross-sectional view of the semiconductor module taken along line F17-F17 in FIG. 16.

FIG. 18 is a cross-sectional view of the semiconductor module taken along line F18-F18 in FIG. 16.

FIG. 19 is a plan view schematically showing the internal structure of a semiconductor unit in a fourth embodiment.

FIG. 20 is a plan view mainly showing the connection configuration of the semiconductor unit shown in FIG. 19.

FIG. 21 is a plan view of the semiconductor unit.

FIG. 22 is a cross-sectional view of the semiconductor unit taken along line F22-F22 in FIG. 21.

FIG. 23 is a cross-sectional view of the semiconductor unit taken along line F23-F23 in FIG. 21.

FIG. 24 is a circuit diagram of the semiconductor unit.

FIG. 25 is a cross-sectional view schematically showing the cross-sectional structure of a pull-down resistor of a semiconductor module in a modified example.

FIG. 26 is a cross-sectional view schematically showing the cross-sectional structure of a pull-down resistor of a semiconductor module in a modified example.

FIG. 27 is a circuit diagram of a semiconductor module in a modified example.

FIG. 28 is a cross-sectional view schematically showing the cross-sectional structure of a protective diode in the semiconductor module shown in FIG. 27.

FIG. 29 is a circuit diagram of a semiconductor module in a modified example.

FIG. 30 is a circuit diagram of a semiconductor module in a modified example.

FIG. 31 is a circuit diagram of a semiconductor unit in a modified example.

### DETAILED DESCRIPTION

Embodiments of a semiconductor module and a semiconductor unit of the present disclosure will be described below with reference to the drawings. In the drawings, components may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

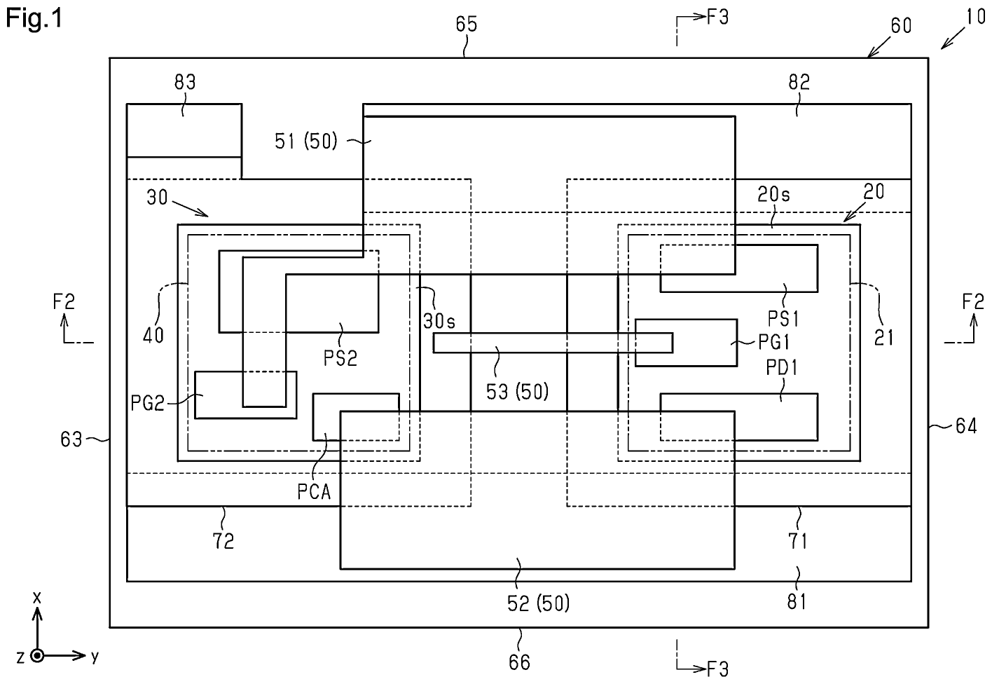

With reference to FIGS. 1 to 9, the configuration of a semiconductor module in a first embodiment will now be described. FIG. 1 schematically shows the internal structure of the semiconductor module. In FIG. 1, to facilitate illustration, components arranged in the semiconductor module are indicated by solid lines.

### Schematic Configuration of Semiconductor Module

As shown in FIG. 1, a semiconductor module 10 includes a first chip 20 including a main transistor 21, a second chip 30 including an active clamp circuit 40, a connection member 50 electrically connecting the main transistor 21 and the active clamp circuit 40, and an encapsulation resin 60 encapsulating the first chip 20, the second chip 30, and the connection member 50.

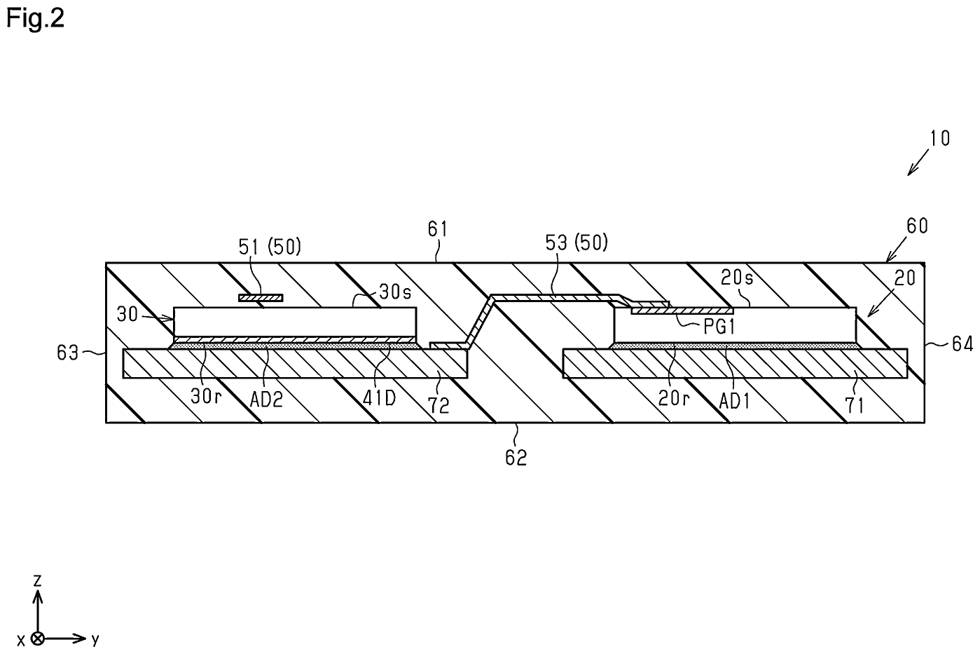

The encapsulation resin 60 is formed from an insulative resin material. Such a resin material includes, for example, an epoxy resin, an acrylic resin, and a phenol resin. The encapsulation resin 60 defines outer surfaces of the semiconductor module 10. In the present embodiment, the encapsulation resin 60 has the form of a rectangular plate. The encapsulation resin 60 includes a resin front surface 61 and a resin back surface 62 (refer to FIG. 2) facing opposite directions and first to fourth resin side surfaces 63 to 66 intersecting with the resin front surface 61 and the resin back surface 62. In the present embodiment, the first to fourth resin side surfaces 63 to 66 are orthogonal to the resin front surface 61 and the resin back surface 62. The direction in which the resin front surface 61 and the resin back surface 62 are arranged refers to the “z-direction.” Also, the thickness-wise direction of the encapsulation resin 60 refers to the z-direction. A view of the semiconductor module 10 taken in the z-direction will be referred to as a “plan view.” In the description hereafter, “plan view” includes the meaning of “view in the thickness-wise direction of the encapsulation resin 60.” Two directions that are orthogonal to each other and orthogonal to the z-direction refer to the “x-direction” and the “y-direction.”

In plan view, the encapsulation resin 60 is rectangular and has a long-side direction and a short-side direction. In the present embodiment, the encapsulation resin 60 is arranged so that the long-side direction is aligned with the y-direction and the short-side direction is aligned with the x-direction. The first resin side surface 63 and the second resin side surface 64 define opposite end surfaces of the encapsulation resin 60 in the y-direction. The third resin side surface 65 and the fourth resin side surface 66 define opposite end surfaces of the encapsulation resin 60 in the x-direction.

The semiconductor module 10 further includes a first die pad 71 on which the first chip 20 is mounted and a second die pad 72 on which the second chip 30 is mounted. The die pads 71 and 72 are formed from a metal material such as copper (Cu), aluminum (Al), or the like. In plan view, the die pads 71 and 72 are rectangular. The first die pad 71 and the second die pad 72 are aligned with each other in the short-side direction (x-direction) of the encapsulation resin 60 and are separated from each other in the long-side direction (y-direction) of the encapsulation resin 60. In the present embodiment, as shown in FIG. 2, the die pads 71 and 72 are aligned with each other in the z-direction. The die pads 71 and 72 are separated from the resin back surface 62 toward the resin front surface 61 in the z-direction and thus are not exposed from the resin back surface 62. Alternatively, the semiconductor module 10 may be configured to expose at least one of the first die pad 71 and the second die pad 72 from the resin back surface 62.

As shown in FIG. 2, the first chip 20 includes a chip front surface 20s and a chip back surface 20r that face opposite directions in the z-direction. The chip front surface 20s faces the same direction as the resin front surface 61. The chip back surface 20r faces the same direction as the resin back surface 62. The chip back surface 20r is opposed to the first die pad 71. The first chip 20 is bonded to the first die pad 71 by a first bonding material AD1. More specifically, the first bonding material AD1 bonds the chip back surface 20r and the first die pad 71. The first bonding material AD1 is, for example, a conductive bonding material such as solder paste or silver (Ag) paste.

As shown in FIG. 1, a drain pad PD1, a source pad PS1, and a gate pad PG1 are formed on the chip front surface 20s. In plan view, the drain pad PD1, the source pad PS1, and the gate pad PG1 are arranged separately from each other. In the present embodiment, the x-direction, that is, the arrangement direction of the drain pad PD1 and the source pad PS1, corresponds to a “first direction.” In plan view, the arrangement direction of the first chip 20 and the second chip 30 is orthogonal to the arrangement direction (first direction) of the drain pad PD1 and the source pad PS1. In the present embodiment, the y-direction, that is, the arrangement direction of the first chip 20 and the second chip 30, corresponds to a “second direction.”

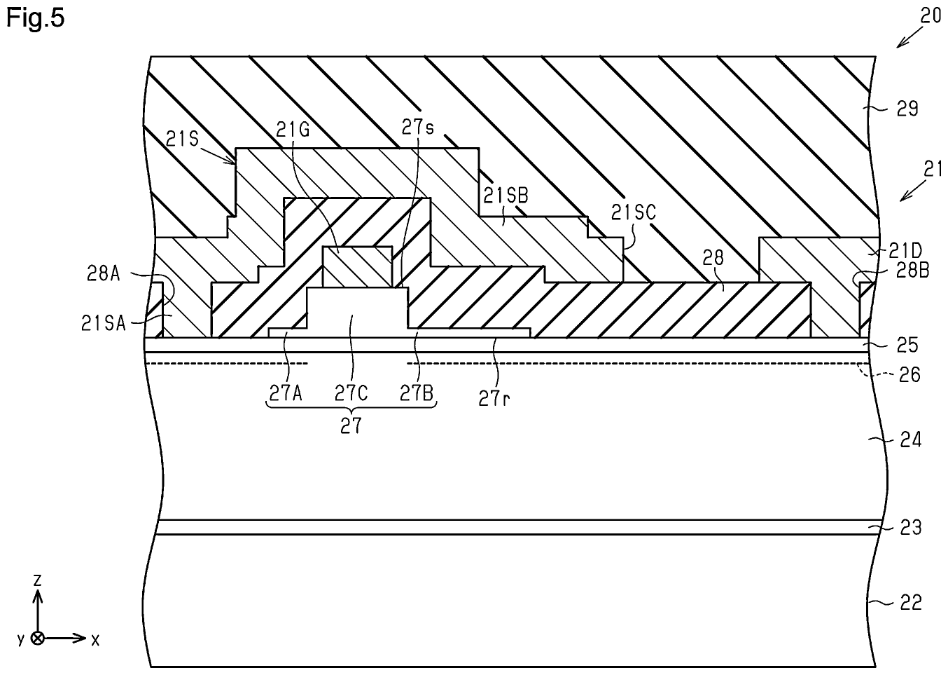

The drain pad PD1 is electrically connected to a drain electrode 21D (refer to FIG. 5) of the main transistor 21. The drain pad PD1 is located closer to the fourth resin side surface 66 than the source pad PS1 and the gate pad PG1 are.

The source pad PS1 is electrically connected to a source electrode 21S (refer to FIG. 5) of the main transistor 21. The source pad PS1 is located closer to the third resin side surface 65 than the drain pad PD1 and the gate pad PG1 are.

The gate pad PG1 is electrically connected to a gate electrode 21G (refer to FIG. 5) of the main transistor 21. The gate pad PG1 is located between the drain pad PD1 and the source pad PS1 in the x-direction. The arrangement of the drain pad PD1, the source pad PS1, and the gate pad PG1 may be changed in any manner.

As shown in FIG. 2, the second chip 30 includes a chip front surface 30s and a chip back surface 30r that face opposite directions in the z-direction. The chip front surface 30s faces the same direction as the resin front surface 61. The chip back surface 30r faces the same direction as the resin back surface 62. The chip back surface 30r is opposed to the second die pad 72. The second chip 30 is bonded to the second die pad 72 by a second bonding material AD2. More specifically, the second bonding material AD2 bonds the chip back surface 30r and the second die pad 72. In the same manner as the first bonding material AD1, the second bonding material AD2 is a conductive bonding material.

As shown in FIG. 1, a source pad PS2, a pad PG2, and a capacitor pad PCA are formed on the chip front surface 30s. In plan view, the source pad PS2, the pad PG2, and the capacitor pad PCA are arranged separately from each other. In the present embodiment, in plan view, the pads PS2, PG2, PCA are arranged separately from each other. In other words, the pads PS2, PG2, and PCA are arranged separately from each other in a direction orthogonal to the arrangement direction (y-direction) of the first chip 20 and the second chip 30. The arrangement of the source pad PS2, the pad PG2 and the capacitor pad PCA may be changed in any manner.

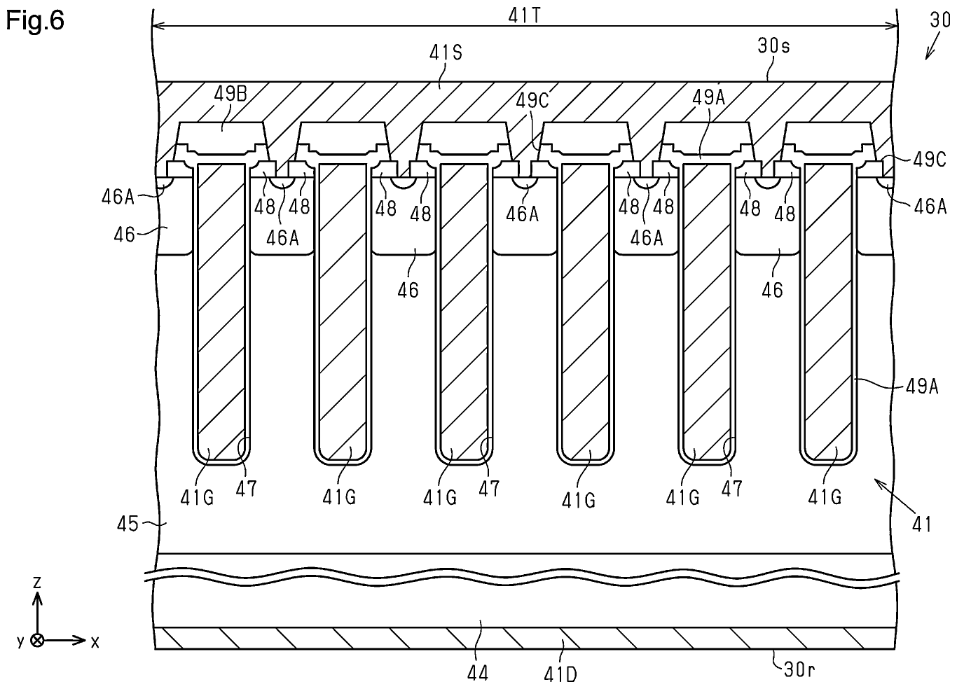

The source pad PS2 is electrically connected to a source electrode 41S of a clamp transistor 41 (refer to FIG. 6) of the active clamp circuit 40. The source pad PS2 is located closer to the third resin side surface 65 than the pad PG2 and the capacitor pad PCA are.

The pad PG2 is electrically connected to a gate electrode 41G (refer to FIG. 6) of the clamp transistor 41 by a pull-down resistor 43. The capacitor pad PCA is electrically connected to a clamp capacitor 42 (refer to FIG. 6) of the active clamp circuit 40. As viewed in the y-direction, the pad PG2 and the capacitor pad PCA are arranged to overlap each other. The pad PG2 is located closer to the first resin side surface 63 than the capacitor pad PCA is.

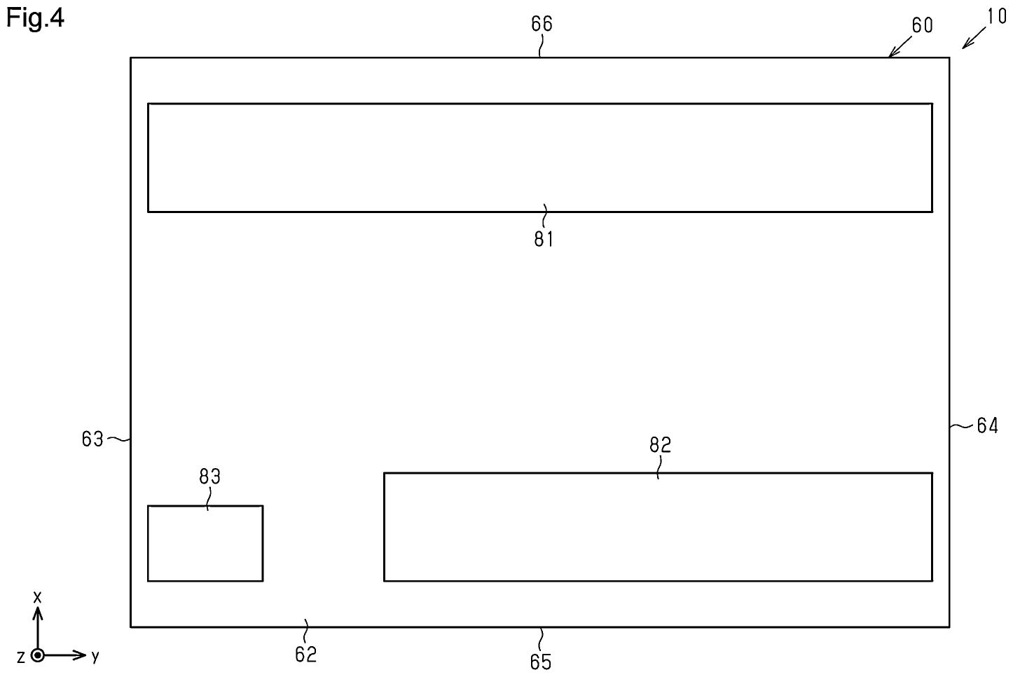

As shown in FIG. 4, the semiconductor module 10 further includes a drain terminal 81, a source terminal 82, and a gate terminal 83, which are used as external terminals. The terminals 81 to 83 are exposed from the resin back surface 62. The terminals 81 to 83 are, for example, formed of a plating layer formed from a conductive material. The conductive material may be, for example, Cu, Al, a CuAl alloy, or the like.

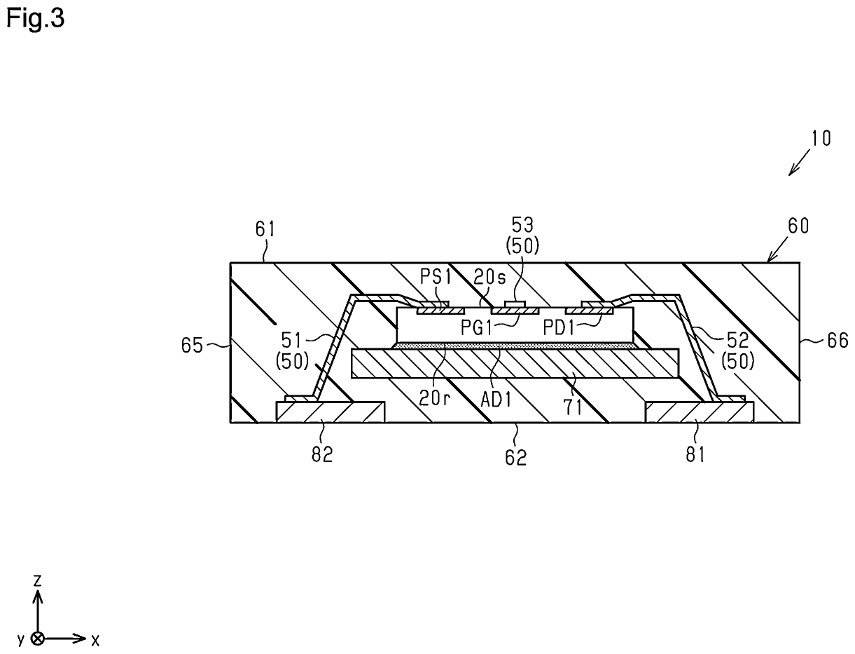

As shown in FIG. 3, the drain terminal 81 and the source terminal 82 are located closer to the resin back surface 62 than the first die pad 71 and the second die pad 72 are in the z-direction. Thus, the first die pad 71 and the second die pad 72 are not exposed from the resin back surface 62. As viewed in the z-direction, the drain terminal 81 and the source terminal 82 are arranged to partially overlap the first die pad 71. Although not shown, the drain terminal 81 and the source terminal 82 are arranged to partially overlap the second die pad 72.

As shown in FIG. 1, the gate terminal 83 is integrated with the second die pad 72. The second die pad 72 includes a mount portion on which the second chip 30 is mounted. The mount portion is located closer to the resin front surface 61 (refer to FIG. 2) than the gate terminal 83 is. In an example, the mount portion and the gate terminal 83 are joined by a joint portion that is inclined toward the resin back surface 62 (refer to FIG. 2) in a direction from the mount portion toward the gate terminal 83. However, the joint portion does not have to be inclined. Alternatively, the gate terminal 83 and the second die pad 72 may be separately arranged and electrically connected to each other by a connection member such as a wire.

As shown in FIG. 1, the connection member 50 includes a first connection member 51, a second connection member 52, and a third connection member 53. In the present embodiment, the connection members 51 to 53 may be formed of, for example, a metal plate. The metal plate may be, for example, Cu, Al, a CuAl alloy, or the like. The connection members 51 to 53 are not limited to a metal plate and may be formed of, for example, a metal plating. That is, the connection members 51 to 53 may be formed of a plating layer.

The first connection member 51 is configured to electrically connect the source terminal 82, the source pad PS1 of the first chip 20, and the source pad PS2 and the pad PG2 of the second chip 30. Thus, the source terminal 82, the source electrode 21S of the main transistor 21, and the source electrode 41S and the pull-down resistor 43 of the clamp transistor 41 are electrically connected.

The second connection member 52 is configured to electrically connect the drain terminal 81, the drain pad PD1 of the first chip 20, and the capacitor pad PCA of the second chip 30. Thus, the drain terminal 81, the drain electrode 21D of the main transistor 21, and the clamp capacitor 42 are electrically connected.

The third connection member 53 is configured to electrically connect the gate pad PG1 of the first chip 20 and the second die pad 72. Thus, the gate electrode 21G of the main transistor 21 is electrically connected to the gate terminal 83.

The shape of the first connection member 51 in plan view is not limited to that of the first connection member 51 shown in FIG. 1 and may be changed in any manner. Also, the shapes of the second connection member 52 and the third connection member 53 may be changed in any manner.

### Detailed Structure of First Chip

FIG. 5 is a cross-sectional view schematically showing an example of the cross-sectional structure of the first chip 20. Some of the hatching lines are not shown for simplicity and clarity.

As shown in FIG. 5, the first chip 20 includes a semiconductor substrate 22. The semiconductor substrate 22 is rectangular-plate-shaped. The semiconductor substrate 22 may be formed from silicon (Si), silicon carbide (SiC), gallium nitride (GaN), sapphire, or other substrate materials. In an example, the semiconductor substrate 22 may be a Si substrate. The semiconductor substrate 22 may have a thickness, for example, in a range of 200 μm to 1500 μm. The main transistor 21 is formed on the semiconductor substrate 22. The main transistor 21 includes a buffer layer 23 formed on the semiconductor substrate 22, an electron transit layer 24 formed on the buffer layer 23 and including a main drift layer, and an electron supply layer 25 formed on the electron transit layer 24. The buffer layer 23, the electron transit layer 24, and the electron supply layer 25 each have a thickness in the z-direction. Hence, “plan view” includes the meaning of “view in the thickness-wise direction of the main drift layer (electron transit layer).”

The buffer layer 23 is arranged between the semiconductor substrate 22 and the electron transit layer 24 and is formed of any material that reduces lattice mismatching between the semiconductor substrate 22 and the electron transit layer 24. The buffer layer 23 includes one or more nitride semiconductor layers. The buffer layer 23 may include, for example, at least one of an aluminum nitride (AlN) layer, an aluminum gallium nitride (AlGaN) layer, and a graded AlGaN layer of different aluminum (Al) compositions. For example, the buffer layer 23 may include a single AlN layer, a single AlGaN layer, a layer having a superlattice structure of AlGaN/GaN, a layer having a superlattice structure of AlN/AlGaN, or a layer having a superlattice structure of AlN/GaN.

In an example, the buffer layer 23 includes a first buffer layer that is an AlN layer formed on the semiconductor substrate 22 and a second buffer layer that is an AlGaN layer formed on the AlN layer. In an example, the first buffer layer is an AlN layer having a thickness of 200 nm. In an example, the second buffer layer has a structure in which multiple AlGaN layers are stacked. To inhibit current leakage of the buffer layer 23, the buffer layer 23 may be partially doped with an impurity so that the buffer layer 23 becomes semi-insulating. In this case, the impurity is, for example, carbon (C) or iron (Fe). The concentration of the impurity may be, for example, greater than or equal to 4×10¹⁶ cm⁻³.

The electron transit layer 24 is composed of a nitride semiconductor and may be, for example, a GaN layer. The thickness of the electron transit layer 24 may be, for example, in a range of 300 nm to 2 μm, and more preferably, in a range of 300 nm to 400 nm. In an example, the thickness of the electron transit layer 24 is 350 nm. As described above, the main transistor 21 is a GaN transistor in which the electron transit layer 24 is composed of GaN as the main drift layer.

To inhibit current leakage of the electron transit layer 24, the electron transit layer 24 may be partially doped with an impurity so that the electron transit layer 24 excluding its surface region becomes semi-insulating. In this case, the impurity is, for example, C. The concentration of the impurity may be, for example, greater than or equal to 1×10¹⁹ cm⁻³ at a peak concentration. More specifically, the electron transit layer 24 may include GaN layers having different impurity concentrations, for example, a C-doped GaN layer and a non-doped GaN layer. The C concentration in the C-doped GaN layer may be in a range of 9×10¹⁸ cm⁻³ to 9×10¹⁹ cm⁻³.

The electron supply layer 25 is composed of a nitride semiconductor having a larger band gap than the electron transit layer 24 and may be, for example, an AlGaN layer. The band gap increases as the Al composition increases. Therefore, the electron supply layer 25, which is an AlGaN layer, has a larger band gap than the electron transit layer 24, which is a GaN layer. In an example, the electron supply layer 25 is composed of Al_{z}Ga_{1-z}N, where 0.1<z<0.4, and more preferably, 0.2<z<0.3. In an example, z=0.25. The electron supply layer 25 has a thickness in a range of, for example, 5 nm to 20 nm. In an example, the electron supply layer 25 has a thickness in a range of 8 nm to 15 nm.

The electron transit layer 24 and the electron supply layer 25 are composed of nitride semiconductors having different lattice constants. A lattice-mismatching junction between the electron transit layer 24 and the electron supply layer 25 imposes strain on the electron supply layer 25. The strain induces a two-dimensional electron gas 26 (2DEG) in the electron transit layer 24. The 2DEG 26 spreads in the electron transit layer 24 at a location close to the heterojunction interface between the electron transit layer 24 and the electron supply layer 25 (for example, approximately a few nanometers away from the interface). The 2DEG 26 is used as a current path (channel) of the main transistor 21.

The main transistor 21 further includes a gate layer 27 formed on a portion of the electron supply layer 25, the gate electrode 21G formed on the gate layer 27, a passivation layer 28, the source electrode 21S, and the drain electrode 21D. The passivation layer 28 covers the electron supply layer 25, the gate layer 27, and the gate electrode 21G and includes a first opening 28A and a second opening 28B. The source electrode 21S is in contact with the electron supply layer 25 through the first opening 28A. The drain electrode 21D is in contact with the electron supply layer 25 through the second opening 28B.

The gate layer 27 is composed of a nitride semiconductor containing an acceptor impurity. The gate layer 27 is formed from, for example, any material having a smaller band gap than the electron supply layer 25, which is an AlGaN layer. In an example, the gate layer 27 is a GaN layer (p-type GaN layer) doped with an acceptor impurity. The acceptor impurity may contain at least one of zinc (Zn), magnesium (Mg), and carbon (C). The maximum concentration of the acceptor impurity in the gate layer 27 is, for example, in a range of 7×10¹⁸ cm⁻³ to 1×10²⁰ cm⁻³. The main transistor 21, which includes the gate layer 27 composed of a nitride semiconductor including an acceptor impurity, depletes the 2DEG 26 in a region immediately below the gate layer 27. This allows the main transistor 21 to perform a normally-off operation. That is, the main transistor 21 is a normally-off transistor.

The gate layer 27 includes a bottom surface 27r in contact with the electron supply layer 25 and an upper surface 27s opposite to the bottom surface 27r. The gate electrode 21G is formed on the upper surface 27s of the gate layer 27.

In the present embodiment, the gate layer 27 includes a ridge 27C including the upper surface 27s, on which the gate electrode 21G is formed, and two extensions (first extension 27A and second extension 27B) extending outward from the ridge 27C in plan view.

In plan view, the first extension 27A extends from the ridge 27C toward the first opening 28A. The first extension 27A is separate from the first opening 28A.

In plan view, the second extension 27B extends from the ridge 27C toward the second opening 28B. The second extension 27B is separate from the second opening 28B.

The ridge 27C is located between the first extension 27A and the second extension 27B and is formed integrally with the first extension 27A and the second extension 27B. Since the gate layer 27 includes the first extension 27A and the second extension 27B, the bottom surface 27r is greater in area than the upper surface 27s. In the present embodiment, the second extension 27B extends longer than the first extension 27A outward from the ridge 27C in plan view.

The ridge 27C corresponds to a relatively thick portion of the gate layer 27 and has a thickness in a range of, for example, 80 nm to 150 nm. The thickness of the gate layer 27, particularly, the ridge 27C, may be determined taking into consideration parameters including the gate threshold voltage. In an example, the thickness of the gate layer 27 (ridge 27C) is greater than 110 nm.

Each of the first extension 27A and the second extension 27B is smaller in thickness than the ridge 27C. In an example, the thickness of each of the first extension 27A and the second extension 27B is less than or equal to one-half of the thickness of the ridge 27C.

In the present embodiment, each of the extensions 27A and 27B is a flat portion having a substantially constant thickness. In this specification, “substantially constant thickness” refers to a thickness being within a manufacturing variation range (for example, 20%). Alternatively, each of the extensions 27A and 27B may include a tapered portion having a thickness that gradually decreases as the ridge 27C becomes farther away in a region abutting the ridge 27C. Each of the extensions 27A and 27B may include a flat portion having a substantially constant thickness in a region located away from the ridge 27C by a predetermined distance. In an example, the flat portion has a thickness in a range of 5 nm to 25 nm.

The gate electrode 21G formed on the ridge 27C is formed of one or more metal layers. The metal layer is, for example, a TiN layer. Alternatively, the gate electrode 21G may include a first metal layer formed of Ti and a second metal layer formed on the first metal layer and formed of TiN. The gate electrode 21G has a thickness in a range of, for example, 50 nm to 200 nm. The gate electrode 21G may form a Schottky junction with the gate layer 27.

The first opening 28A and the second opening 28B of the passivation layer 28 are separate from the gate layer 27. The gate layer 27 is arranged between the first opening 28A and the second opening 28B. More specifically, the gate layer 27 is arranged between the first opening 28A and the second opening 28B at a position closer to the first opening 28A than to the second opening 28B. The passivation layer 28 extends along the upper surface of the electron supply layer 25, the side surface and the upper surface 27s of the gate layer 27, and the side surface and the upper surface of the gate electrode 21G. Thus, the passivation layer 28 includes a non-flat surface.

The source electrode 21S and the drain electrode 21D are formed of one or more metal layers. The metal layer may include any combination of, for example, a Ti layer, a TiN layer, an Al layer, an AlSiCu layer, and an AlCu layer. At least a portion of the source electrode 21S fills the first opening 28A. At least a portion of the drain electrode 21D fills the second opening 28B. The source electrode 21S is in ohmic contact with the 2DEG 26 present immediately below the electron supply layer 25 through the first opening 28A. The drain electrode 21D is in ohmic contact with the 2DEG 26 present immediately below the electron supply layer 25 through the second opening 28B.

The source electrode 21S includes a source contact 21SA filling the first opening 28A and a source field plate 21SB covering the passivation layer 28. The source field plate 21SB is formed integrally with the source contact 21SA. In plan view, the source field plate 21SB includes an end 21SC located between the second opening 28B and the gate layer 27 in plan view. The source field plate 21SB extends from the source contact 21SA to the end 21SC along the surface of the passivation layer 28 toward the drain electrode 21D but is spaced apart from the drain electrode 21D. Since the source field plate 21SB extends along the non-flat surface of the passivation layer 28, the source field plate 21SB includes a non-flat surface in the same manner. In a state in which no gate voltage is applied to the gate electrode 21G, that is, in the zero bias state, when a drain voltage is applied to the drain electrode 21D, the source field plate 21SB lessens the concentration of electric field in the vicinity of the end of the gate electrode 21G.

The drain electrode 21D and the source electrode 21S are covered by an inter-layer insulation layer 29. The inter-layer insulation layer 29 includes an interconnect layer (not shown). The interconnect layer includes a drain interconnect electrically connecting the drain electrode 21D and the drain pad PD1 (refer to FIG. 1), a source interconnect electrically connecting the source electrode 21S and the source pad PS1 (refer to FIG. 1), and a gate interconnect electrically connecting the gate electrode 21G and the gate pad PG1 (refer to FIG. 1).

Thus, the first chip 20 does not include the active clamp circuit 40 and includes the main transistor 21. In the present embodiment, in the first chip 20, only the main transistor 21 is formed on the semiconductor substrate 22.

### Detailed Structure of Second Chip

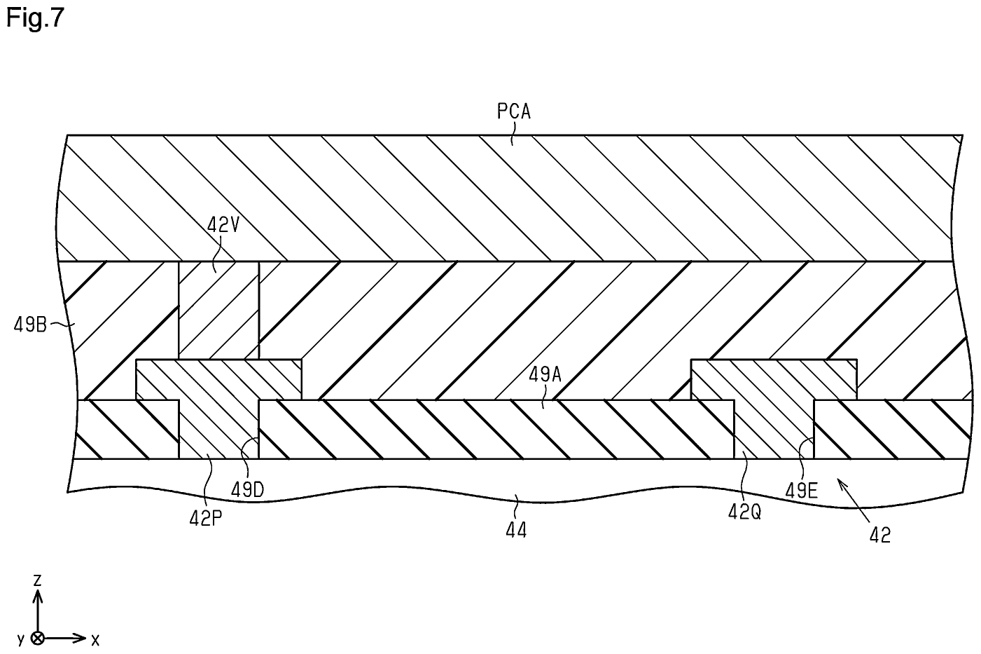

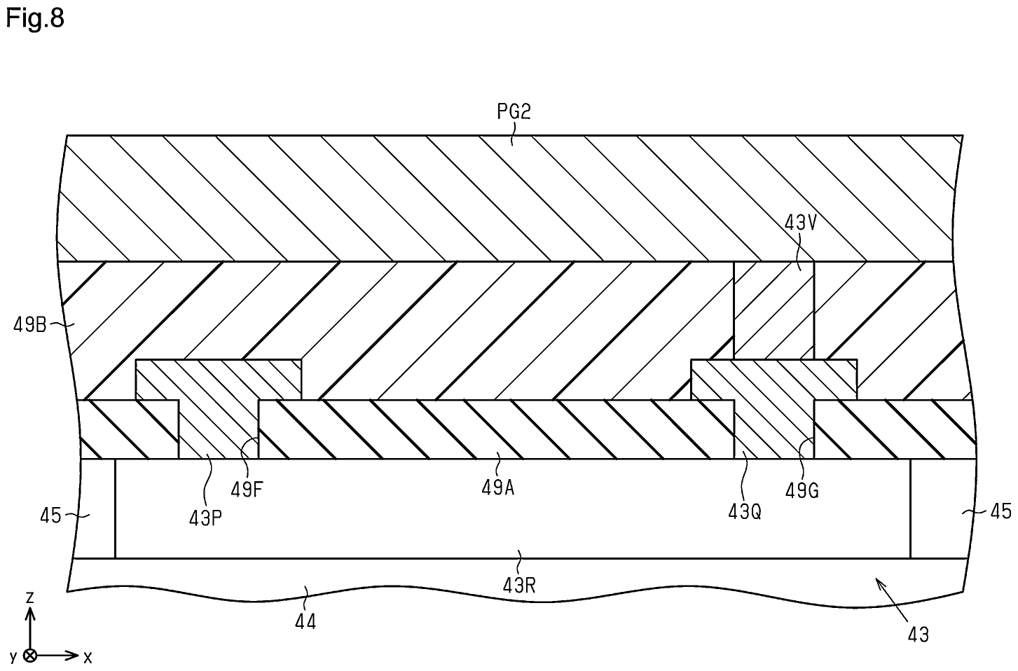

As shown in FIG. 1, the active clamp circuit 40 is configured to inhibit occurrence of erroneous turn-on due to a sharp change in the drain-source voltage when the main transistor 21 is in a deactivation state. The active clamp circuit 40 includes the clamp transistor 41 (refer to FIG. 6), which is an example of a sub transistor, the clamp capacitor 42 (refer to FIG. 7), and the pull-down resistor 43 (refer to FIG. 8). The clamp transistor 41, the clamp capacitor 42, and the pull-down resistor 43 are electrically connected to each other in the second chip 30.

In plan view, the pull-down resistor 43 is arranged to overlap the pad PG2. In the present embodiment, the clamp transistor 41 is formed in a main region of the second chip 30. The clamp capacitor 42 is formed in a region of the second chip 30 other than the region where the clamp transistor 41 is formed. In an example, in plan view, the region where the clamp capacitor 42 is formed and the region where the pull-down resistor 43 is formed are each approximately 1/100 of the area of the pad PG2. In FIG. 1, for the sake of convenience, the capacitor pad PCA is enlarged. The actual capacitor pad PCA is smaller than the pad PG2.

FIG. 6 is a cross-sectional view of an example of the schematic cross-sectional structure of the second chip 30 showing the cross-sectional structure of part of an active region 41T of the clamp transistor 41. Some of the hatching lines are not shown for simplicity and clarity. The active region 41T of the clamp transistor 41 refers to a region in which a transistor is formed.

As shown in FIG. 6, the second chip 30 includes a semiconductor substrate 44. The semiconductor substrate 44 is rectangular-plate-shaped. The semiconductor substrate 44 may be formed of Si, SiC, GaN, sapphire, or other substrate materials. In an example, the semiconductor substrate 44 may be a Si substrate. The semiconductor substrate 44 may have a thickness, for example, in a range of 200 μm to 1500 μm. The clamp transistor 41 is formed on the semiconductor substrate 22. The clamp capacitor 42 (refer to FIG. 7) and the pull-down resistor 43 (refer to FIG. 8) are formed on the semiconductor substrate 44.

The clamp transistor 41 includes a n⁻-type drift layer 45 formed on the semiconductor substrate 44. In other words, the semiconductor substrate 44 supports the drift layer 45. The drift layer 45 is an example of a sub drift layer and is composed of a material that differs from the material composing the electron transit layer 24 (refer to FIG. 5), which includes a main drift layer. The drift layer 45 is formed from a material including, for example, Si. For example, N, phosphorus (P), arsenic (As), or the like is used as an n-type impurity of the drift layer 45. The impurity concentration of the drift layer 45 is, for example, in a range of 1×10¹³ cm⁻³ to 5×10¹⁴ cm⁻³. As described above, the clamp transistor 41 is a transistor in which the drift layer 45, including the sub drift layer, is formed from a material including Si. In the present embodiment, the clamp transistor 41 is a Si transistor in which the drift layer 45 is formed from Si. Alternatively, the clamp transistor 41 may be a SiC transistor in which the drift layer 45 is formed from SiC.

A p-type base region 46 is formed on a surface of the drift layer 45. For example, boron (B), Al, or the like is used as a p-type dopant of the base region 46. The base region 46 has an impurity concentration in, for example, a range of 1×10¹⁶ cm⁻³ to 1×10¹⁸ cm⁻³.

Trenches 47 are arranged next to each other in the surface of the base region 46. In an example, the trenches 47 extend in the y-direction and are separated from each other in the x-direction. The trenches 47 extend through the base region 46 in the z-direction to an intermediate portion of the drift layer 45. The trenches 47 may be arranged in a lattice pattern in plan view.

An n⁺-type source region 48 is formed on the surface of the base region 46 at opposite sides of the trench 47 in the x-direction. In other words, the source region 48 is formed on the surface of the drift layer 45. The impurity concentration of the source region 48 is higher than the impurity concentration of the base region 46 and is, for example, in a range of 1×10¹⁹ cm⁻³ to 5×10²⁰ cm⁻³.

A p⁺-type base contact region 46A is formed on the surface of the base region 46 adjacent to the source region 48 in the x-direction. The base contact region 46A is arranged, in the x-direction, between two source regions 48 arranged, in the x-direction, between the trenches 47 located adjacent to each other in the x-direction. The impurity concentration of the base contact region 46A is higher than that of the base region 46 and is, for example, in a range of 5×10¹⁸ cm⁻³ to 1×10²⁰ cm⁻³.

An insulation film 49A is integrally formed on the wall surface of each trench 47 and the surface of the base region 46. The insulation film 49A is formed from a material including, for example, SiO₂. An electrode material formed from, for example, polysilicon, is embedded in each trench 47 with the insulation film 49A. This forms the gate electrode 41G.

An intermediate insulation film 49B is formed on the insulation film 49A that is formed on the surface of the base region 46. The intermediate insulation film 49B is formed from a material including, for example, SiO₂. The intermediate insulation film 49B is greater in thickness than the insulation film 49A. The source electrode 41S is formed on the intermediate insulation film 49B.

The insulation film 49A and the intermediate insulation film 49B each include openings 49C exposing the base contact region 46A. The source electrode 41S is embedded in the openings 49C to contact the base contact region 46A.

A drain electrode 41D is formed on a back surface of the semiconductor substrate 44 located at a side opposite from the drift layer 45 in the z-direction. The drain electrode 41D and the source electrode 41S are formed from a material including, for example, at least one of titanium (Ti), tungsten (W), Al, Cu, and an AlCu alloy.

FIG. 7 is a cross-sectional view showing an example of the cross-sectional structure of the clamp capacitor 42.

As shown in FIG. 7, the clamp capacitor 42 is arranged to overlap the capacitor pad PCA in plan view. In plan view, the region of the second chip 30 that overlaps the capacitor pad PCA differs from the active region of the clamp transistor 41. Thus, as shown in FIG. 7, in plan view, the region overlapping the capacitor pad PCA has a structure in which the insulation film 49A is formed on the semiconductor substrate 44.

The clamp capacitor 42 includes a first electrode 42P and a second electrode 42Q. The first electrode 42P and the second electrode 42Q are separated from each other by the insulation film 49A. More specifically, two openings 49D and 49E are separated from each other and formed in the insulation film 49A to expose the semiconductor substrate 44. The first electrode 42P fills the opening 49D and extends out to an edge extending around the opening 49D. The second electrode 42Q fills the opening 49E and extends out to an edge extending around the opening 49E. The portion of the first electrode 42P extending out of the opening 49D and the portion of the second electrode 42Q extending out of the opening 49E are covered by the intermediate insulation film 49B. The insulation film 49A formed between the first electrode 42P and the second electrode 42Q, that is, the portion of the insulation film 49A located between the opening 49D and the opening 49E, includes a dielectric layer. The first electrode 42P is electrically connected to the capacitor pad PCA by, for example, a via 42V

FIG. 8 is a cross-sectional view showing an example of the cross-sectional structure of the pull-down resistor 43.

As shown in FIG. 8, in plan view, the pull-down resistor 43 is arranged to overlap the pad PG2. The pull-down resistor 43 includes a first terminal 43P, a second terminal 43Q, and a plate-shaped resistor part 43R. The second terminal 43Q is electrically connected to the pad PG2 by, for example, a via 43V.

The first terminal 43P and the second terminal 43Q are separated from each other by the insulation film 49A. More specifically, two openings 49F and 49G are separated from each other and formed in the insulation film 49A to expose the resistor part 43R. The first terminal 43P fills the opening 49F and extends out to an edge extending around the opening 49F. The second terminal 43Q fills the opening 49G and extends out to an edge extending around the opening 49G. The portion of the first terminal 43P extending out of the opening 49F and the portion of the second terminal 43Q extending out of the opening 49G are covered by the intermediate insulation film 49B.

The resistor part 43R is formed on the semiconductor substrate 44. The resistor part 43R is formed from a material having a greater resistance than the material forming the first terminal 43P and the second terminal 43Q. In an example, the resistor part 43R is formed from, for example, polysilicon.

The first terminal 43P and the second terminal 43Q are arranged on the resistor part 43R. The first terminal 43P and the second terminal 43Q are electrically connected to the resistor part 43R. More specifically, the terminals 43P and 43Q are in ohmic contact with the resistor part 43R. In plan view, the first terminal 43P and the second terminal 43Q are separately formed on two ends of the resistor part 43R in the y-direction. Thus, the pull-down resistor 43 is formed on the insulation film 49A and covered by the intermediate insulation film 49B.

As shown in FIGS. 7 and 8, the first electrode 42P and the second electrode 42Q of the clamp capacitor 42, the vias 42V and 43V, and the first terminal 43P and the second terminal 43Q of the pull-down resistor 43 may be formed from, for example, any conductive material including at least one of Cu, Al, an AlCu alloy, W, Ti, and TiN.

Thus, the second chip 30 does not include the main transistor 21 and includes the active clamp circuit 40. More specifically, the second chip 30 includes the clamp transistor 41, the clamp capacitor 42, and the pull-down resistor 43. In the present embodiment, the second chip 30 includes only the clamp transistor 41, the clamp capacitor 42, and the pull-down resistor 43.

### Circuit Configuration of Semiconductor Module

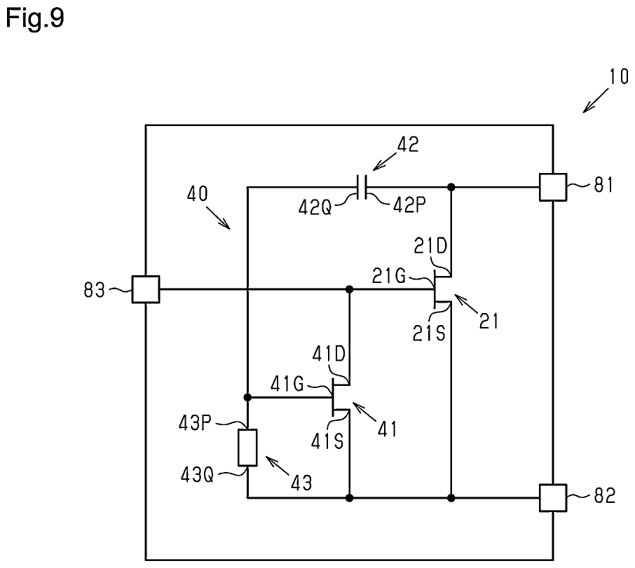

FIG. 9 shows the circuit configuration of the semiconductor module 10. As shown in FIG. 9, the active clamp circuit 40 is connected to the main transistor 21. More specifically, the source electrode 41S of the clamp transistor 41 is connected to the source electrode 21S of the main transistor 21. The drain electrode 41D of the clamp transistor 41 is connected to the gate electrode 21G of the main transistor 21. The clamp capacitor 42 is connected between the drain electrode 21D of the main transistor 21 and the gate electrode 41G of the clamp transistor 41. The pull-down resistor 43 is connected between the source electrode 41S and the gate electrode 41G of the clamp transistor 41.

The drain electrode 21D of the main transistor 21 and the clamp capacitor 42 are connected to the drain terminal 81. The source electrode 21S of the main transistor 21, the source electrode 41S of the clamp transistor 41, and the pull-down resistor 43 are connected to the source terminal 82. The gate electrode 21G of the main transistor 21 and the drain electrode 41D of the clamp transistor 41 are connected to the gate terminal 83.

### Operation

The operation of the present embodiment will now be described. A semiconductor module that does not include the second chip 30 is referred to as a “comparative semiconductor module.” The comparative semiconductor module includes only the first chip 20. The first chip 20 (main transistor 21) is used for, for example, a DC-DC converter.

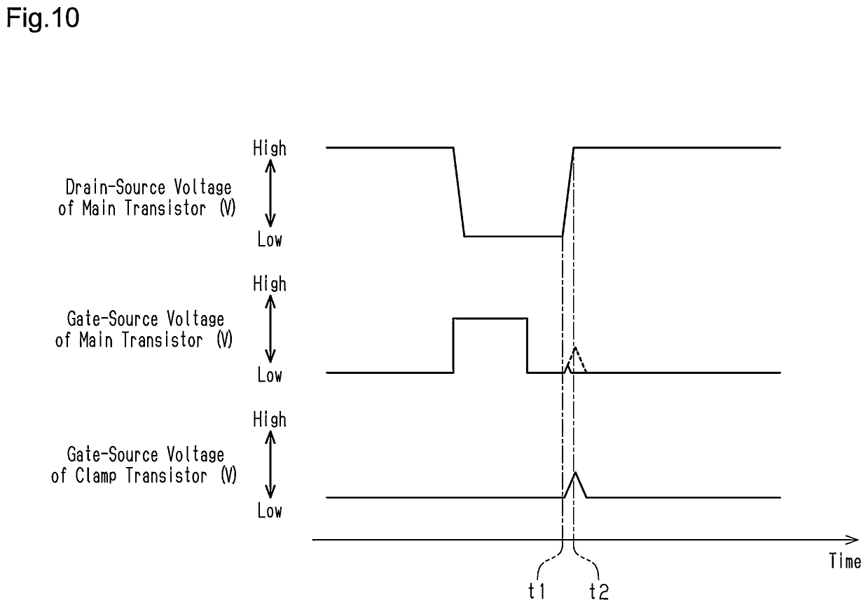

As shown in FIG. 10, in the comparative semiconductor module, while the main transistor 21 is turned off, the drain-source voltage of the main transistor 21 may change sharply during a period from time t1 to time t2. This occurs, for example, due to an element (e.g., coil of DC-DC converter) that is connected to the main transistor 21. At this time, as indicated by the broken lines in the middle section of FIG. 10, the gate-source voltage (gate voltage) of the main transistor 21 is increased by gate-drain parasitic capacitance of the main transistor 21. When the gate-source voltage exceeds the threshold value of the main transistor 21, the main transistor 21 will turn on. In other words, in the comparative semiconductor module, even when the main transistor 21 is expected to be in a deactivation state, the main transistor 21 enters an activation state (erroneous turn-on).

In this regard, in the present embodiment, the clamp transistor 41 is configured to be activated based on a rise of the drain-source voltage of the main transistor 21. More specifically, the clamp transistor 41 is configured to be turned on earlier than the main transistor 21 in response to a sharp change in the drain-source voltage of the main transistor 21. In an example, the capacitance of the clamp capacitor 42 is set so that the voltage of the second electrode 42Q rapidly increases as compared to the gate-source voltage of the main transistor 21. For example, the clamp capacitor 42 has a capacitance that is set to be smaller than the gate-drain capacitance of the main transistor 21. The clamp transistor 41 may have a threshold voltage that is set to be lower than the threshold voltage of the main transistor 21.

When the above-described clamp capacitor 42 is connected to the gate electrode 41G of the clamp transistor 41, the gate-source voltage of the clamp transistor 41 will be increased by a sharp change in the drain-source voltage of the main transistor 21. This activates the clamp transistor 41 and allows the gate electrode 21G and the source electrode 21S of the main transistor 21 to be connected through the clamp transistor 41. As a result, the gate-source voltage of the main transistor 21 shifts from increasing to decreasing before reaching a complete rise. Thus, as indicated by the solid lines in the middle section in FIG. 10, an increase in the gate-source voltage of the main transistor 21 is limited. As a result, erroneous turn-on of the main transistor 21 is inhibited.

When the comparative semiconductor module is provided with the active clamp circuit 40 as a measure against the erroneous turn-on, the active clamp circuit 40 (second chip 30) may be arranged on a circuit substrate arranged outside the comparative semiconductor module. In this configuration, in the comparative semiconductor module, the main transistor 21 is connected to the active clamp circuit 40, which is arranged on the circuit substrate, by a conductive path such as interconnects arranged on the circuit substrate. If the conductive path is long, the conductive path has a high parasitic impedance. In addition, the conductive path may have a parasitic inductance that delays activation of the active clamp circuit 40 in response to a sharp change in the drain-source voltage of the main transistor 21. Therefore, when the drain-source voltage of the main transistor 21 changes sharply, the gate-source voltage may increase, and the main transistor 21 may be erroneously turned on.

In the present embodiment, the semiconductor module 10 includes the first chip 20 and the second chip 30. In other words, the semiconductor module 10 includes the main transistor 21 and the active clamp circuit 40. This allows the main transistor 21 and the active clamp circuit 40 to be electrically connected to each other in the semiconductor module 10. Thus, the conductive path between the main transistor 21 and the active clamp circuit 40 is shortened as compared to a structure in which the active clamp circuit 40 (second chip 30) is arranged on a circuit substrate arranged outside the comparative semiconductor module. This decreases the parasitic impedance and the parasitic inductance of the conductive path. As a result, erroneous turn-on of the main transistor 21 is inhibited.

### Advantages

The first embodiment has the following advantages.

(1-1) The semiconductor module 10 includes the first chip 20, the second chip 30, the connection member 50, and the encapsulation resin 60 encapsulating the first chip 20, the second chip 30, and the connection member 50. The first chip 20 includes the main transistor 21 including the electron transit layer 24 including a main drift layer. The second chip 30 includes at least part of the active clamp circuit 40 including the clamp transistor 41 configured to be activated based on a rise of drain-source voltage of the main transistor 21. The connection member 50 electrically connects the main transistor 21 and the active clamp circuit 40. The clamp transistor 41 includes the drift layer 45 as a sub drift layer composed of a material differing from the material composing the main drift layer (electron transit layer 24).

With this configuration, when the drain-source voltage of the main transistor 21 changes sharply, the clamp transistor 41 limits an increase in the gate-source voltage of the main transistor 21. Thus, erroneous turn-on of the main transistor 21 is inhibited.

The main transistor 21 and the active clamp circuit 40 are electrically connected to each other in the semiconductor module 10. Thus, the conductive path between the main transistor 21 and the active clamp circuit 40 is shortened. This decreases the parasitic impedance and the parasitic inductance of the conductive path, thereby further inhibiting erroneous turn-on of the main transistor 21.

The electron transit layer 24, used as the main drift layer, and the drift layer 45, used as the sub drift layer, are formed from different materials. Thus, a material suitable for each application may be used. For example, when the main transistor 21 is a power transistor such as a GaN transistor or a SiC transistor, the clamp transistor 41 may be a general-purpose transistor that differs from a power transistor.

(1-2) The main transistor 21 is a GaN transistor in which the electron transit layer 24 is composed of GaN. The clamp transistor 41 is a Si transistor in which the drift layer 45 is composed of Si. This configuration reduces the costs of the clamp transistor 41 as compared to a configuration in which the clamp transistor 41 is a GaN transistor.

(1-3) The first chip 20 does not include the active clamp circuit 40 and includes the main transistor 21. The second chip 30 includes the clamp transistor 41, the clamp capacitor 42, and the pull-down resistor 43. The clamp transistor 41, the clamp capacitor 42, and the pull-down resistor 43 are electrically connected to each other in the second chip 30.

In this structure, the first chip 20 and the second chip 30 are electrically connected in a simple manner as compared to a structure in which the first chip 20 includes part of the active clamp circuit 40.

(1-4) The second chip 30 includes the pad PG2. The pad PG2 is connected to the gate electrode 41G of the clamp transistor 41 by the pull-down resistor 43. In plan view, the pull-down resistor 43 is arranged to overlap the pad PG2. The pull-down resistor 43 is located closer to the drift layer 45 than the pad PG2 is.

This structure allows for enlargement of the active region of the clamp transistor 41 as compared to a structure in which the pull-down resistor 43 and the pad PG2 are formed in different regions in plan view. When the active region is not enlarged, the area of the second chip 30 may be decreased in plan view.

(1-5) The first connection member 51, the second connection member 52, and the third connection member 53 are each formed of a metal plate.

In this configuration, the structure of the encapsulation resin 60 is simplified as compared to a configuration in which the connection members 51 to 53 include interconnects and vias formed of, for example, plating layers. This reduces the number of steps for manufacturing the semiconductor module 100.

(1-6) The first chip 20 includes the drain pad PD1 electrically connected to the drain electrode 21D of the main transistor 21 and the source pad PS1 electrically connected to the source electrode 21S of the main transistor 21. In plan view, the drain pad PD1 and the source pad PS1 are arranged separately from each other in the x-direction. In plan view, the first chip 20 and the second chip 30 are arranged separately from each other in the y-direction.

This configuration simplifies the structure of the connection member 50, which electrically connects the active clamp circuit 40 to the drain electrode 21D and the source electrode 21S of the main transistor 21.

(1-7) The active clamp circuit 40 includes the pull-down resistor 43 connected between the source electrode 41S and the gate electrode 41G of the clamp transistor 41 and the clamp capacitor 42 connected between the drain electrode 21D of the main transistor 21 and the gate electrode 41G of the clamp transistor 41.

In this configuration, when the drain-source voltage of the main transistor 21 changes sharply, the sharp voltage change increases the gate-source voltage of the clamp transistor 41 and activates the clamp transistor 41. As a result, an increase in the gate-source voltage of the main transistor 21 is limited. As described above, activation and deactivation of the clamp transistor 41 is controlled within the semiconductor module 10 instead of being controlled based on a signal from a circuit arranged outside the semiconductor module 10. This eliminates the need to provide the semiconductor module 10 with an additional pad for the signal. Thus, addition of pads for the active clamp circuit 40 on the semiconductor module 10 is limited.

### Second Embodiment

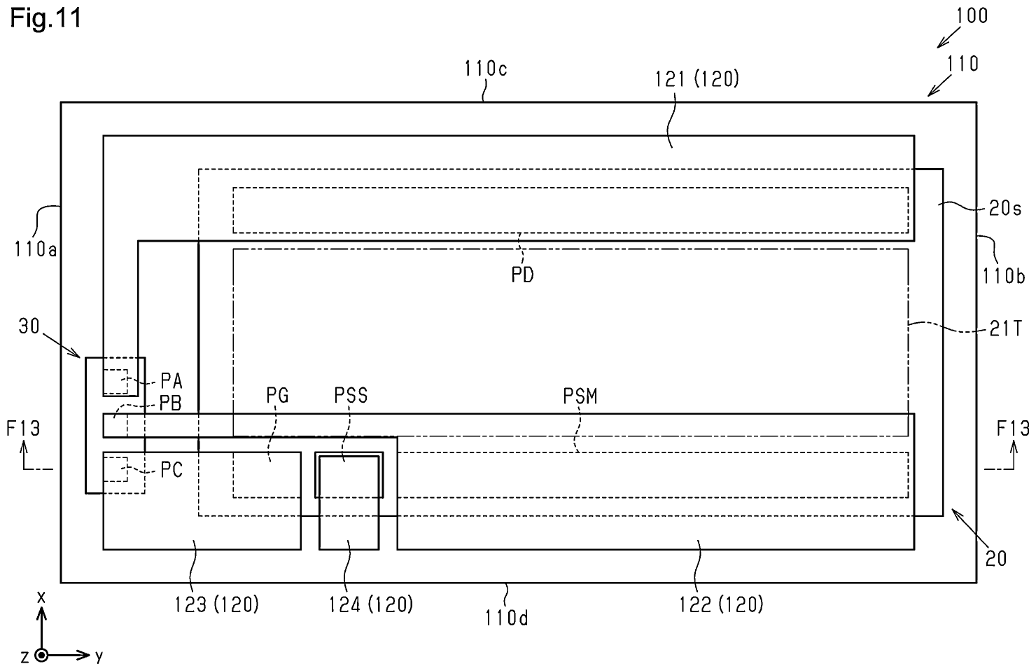

A second embodiment of a semiconductor module 100 will now be described with reference to FIGS. 11 to 15. The semiconductor module 100 of the present embodiment differs from the semiconductor module 10 of the first embodiment in mainly the configurations of the first chip 20 and the second chip 30. In the description below, the same reference characters are given to those components that are the same as the corresponding components of the first embodiment. Such components will not be described in detail.

### Schematic Configuration of Semiconductor Module

The schematic configuration of the semiconductor module 100 will be described with reference to FIGS. 11 to 13.

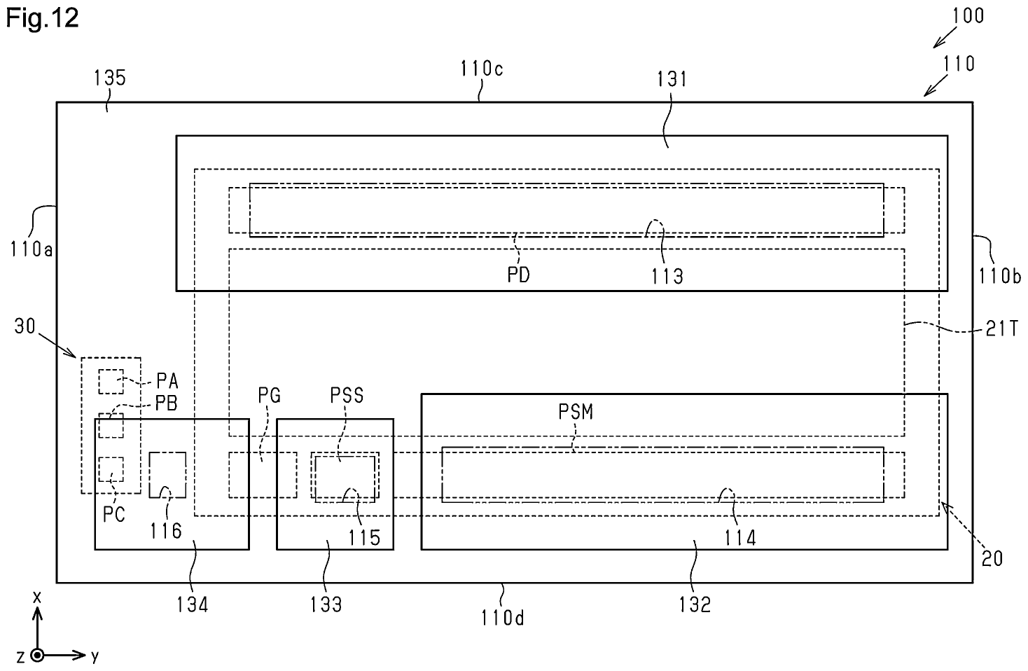

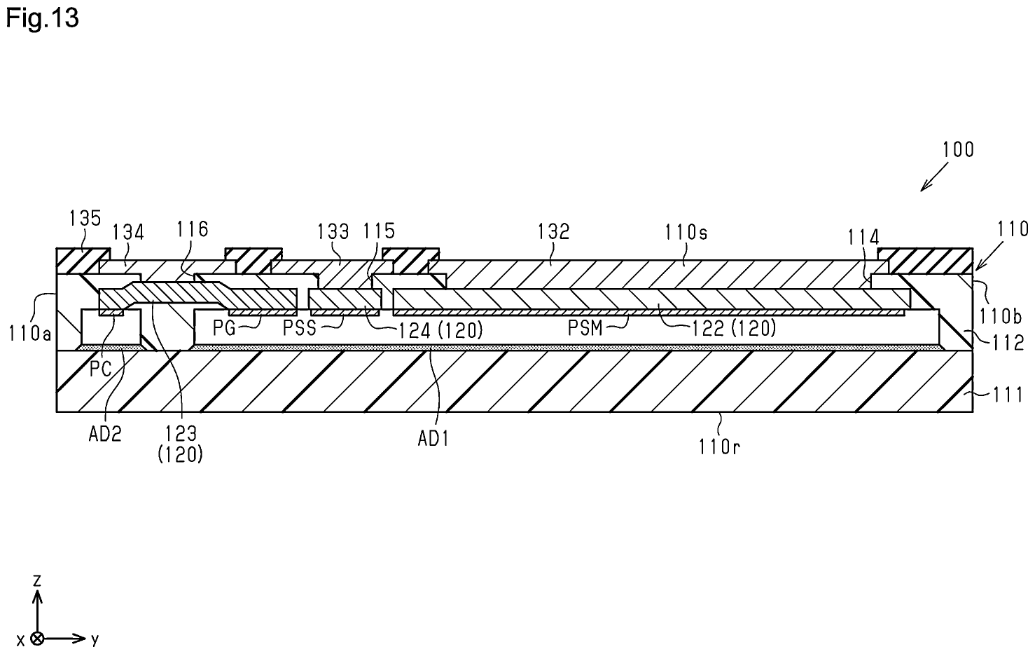

FIG. 11 is a plan view of the internal structure of the semiconductor module 100 mainly showing an example of the arrangement configuration and connection configuration of the first chip 20 and the second chip 30. FIG. 12 is a plan view of the semiconductor module 100. FIG. 13 is a cross-sectional view of the semiconductor module 100 taken along line F13-F13 in FIG. 11, mainly showing the cross-sectional structure of the first chip 20 and the second chip 30. In FIG. 12, openings 113 to 116, which will be described later, are indicated by double-dashed lines for the sake of convenience.

As shown in FIG. 11, the semiconductor module 100 includes the first chip 20, the second chip 30, and an encapsulation resin 110 encapsulating the chips 20 and 30. In FIG. 11, the chips 20 and 30, located in the encapsulation resin 110, are indicated by solid lines to facilitate illustration.

The semiconductor module 100 has the form of a rectangular plate. The encapsulation resin 110 defines outer surfaces of the semiconductor module 100. That is, the encapsulation resin 110 has the form of a rectangular plate. The encapsulation resin 110 includes a resin front surface 110s and a resin back surface 110r (refer to FIG. 13) that face opposite directions and first to fourth resin side surfaces 110a to 110d, which are four resin side surfaces intersecting the resin front surface 110s and the resin back surface 110r. In the present embodiment, the first to fourth resin side surfaces 110a to 110d are orthogonal to the resin front surface 110s and the resin back surface 110r. In the present embodiment, the thickness-wise direction of the encapsulation resin 110 refers to the z-direction. In the description, “plan view” includes the meaning of “view in the thickness-wise direction of the encapsulation resin 110.”

In plan view, the encapsulation resin 110 is rectangular and has a long-side direction and a short-side direction. In the present embodiment, the encapsulation resin 110 is arranged so that the long-side direction is aligned with the y-direction and the short-side direction is aligned with the x-direction. In the present embodiment, the first resin side surface 110a and the second resin side surface 110b define opposite end surfaces of the encapsulation resin 110 in the long-side direction (y-direction) and the third resin side surface 110c and the fourth resin side surface 110d define opposite end surfaces of the encapsulation resin 110 in the short-side direction (x-direction). The encapsulation resin 110 is formed from an insulative resin material. Such a resin material includes, for example, an epoxy resin, an acrylic resin, and a phenol resin.

As shown in FIG. 13, the encapsulation resin 110 includes a first encapsulation portion 111 and a second encapsulation portion 112. The first encapsulation portion 111 is a support substrate that supports the first chip 20 and the second chip 30. The first encapsulation portion 111 includes the resin back surface 110r. The second encapsulation portion 112 is formed on the first encapsulation portion 111 and encapsulates the first chip 20 and the second chip 30 in cooperation with the first encapsulation portion 111. The second encapsulation portion 112 includes the resin front surface 110s. The first chip 20 is bonded to the first encapsulation portion 111 by the first bonding material AD1. The second chip 30 is bonded to the first encapsulation portion 111 by the second bonding material AD2. The bonding materials AD1 and AD2 may each be a conductive bonding material or an insulative bonding material.

As shown in FIG. 11, the first chip 20 differs in shape from the first chip 20 of the first embodiment. In the present embodiment, the first chip 20 has the form of a rectangular plate having a long-side direction and a short-side direction. The first chip 20 is arranged so that the long-side direction of the first chip 20 is aligned with the long-side direction of the encapsulation resin 110 and the short-side direction of the first chip 20 is aligned with the short-side direction of the encapsulation resin 110. In plan view, the first chip 20 is formed on a substantial portion of the encapsulation resin 110.

The first chip 20 includes a drain pad PD electrically connected to the drain electrode 21D (refer to FIG. 6) of the main transistor 21, a main source pad PSM and a sense source pad PSS electrically connected to the source electrode 21S (refer to FIG. 6) of the main transistor 21, and a gate pad PG electrically connected to the gate electrode 21G (refer to FIG. 6) of the main transistor 21.

In the first chip 20, the drain pad PD is located closer to the third resin side surface 110c than the center of the encapsulation resin 110 in the x-direction. The main source pad PSM, the sense source pad PSS, and the gate pad PG are located closer to the fourth resin side surface 110d than the center of the encapsulation resin 110 in the x-direction. The gate pad PG is located closer to the first resin side surface 110a than the main source pad PSM and the sense source pad PSS are.

The main transistor 21 includes an active region 21T. The active region 21T is a region in which a transistor is formed. In the present embodiment, in plan view, the active region 21T is rectangular and has a long-side direction and a short-side direction. The active region 21T is arranged so that the long-side direction of the active region 21T is aligned with the long-side direction of the first chip 20 and the short-side direction of the active region 21T is aligned with the short-side direction of the first chip 20. The drain pad PD is located closer to the third resin side surface 110c than the active region 21T is. The main source pad PSM, the sense source pad PSS, and the gate pad PG are located closer to the fourth resin side surface 110d than the active region 21T is.

The second chip 30 differs in shape from the second chip 30 of the first embodiment. In the present embodiment, the second chip 30 has the form of a rectangular plate having a long-side direction and a short-side direction. In plan view, the area (second area) of the second chip 30 is smaller than the area (first area) of the first chip 20. In an example, the second area is less than or equal to ½ of the first area. In an example, the second area is less than or equal to ⅕ of the first area. In an example, the second area is less than or equal to 1/10 of the first area.

The second chip 30 is arranged so that the long-side direction of the second chip 30 is aligned with the short-side direction of the encapsulation resin 110 and the short-side direction of the second chip 30 is aligned with the long-side direction of the encapsulation resin 110. The second chip 30 is located closer to the first resin side surface 110a than the first chip 20 is. Thus, the first chip 20 and the second chip 30 are separated from each other in the long-side direction (y-direction) of the encapsulation resin 110. The long-side direction of the first chip 20 is aligned with the arrangement direction of the first chip 20 and the second chip 30. The long-side direction of the second chip 30 is orthogonal to the arrangement direction of the first chip 20 and the second chip 30 in plan view.

In the present embodiment, the second chip 30 is located closer to the fourth resin side surface 110d than the center of the encapsulation resin 110 in the x-direction is. In other words, the second chip 30 is located closer to the gate pad PG than the drain pad PD of the first chip 20 is.

The second chip 30 includes a first pad PA, a second pad PB, and a third pad PC. The pads PA to PC are aligned with each other in the short-side direction (y-direction) of the second chip 30 and are separated from each other in the long-side direction (x-direction) of the second chip 30. The pads PA to PC are arranged at the center of the second chip 30 in the short-side direction (y-direction).

In the present embodiment, the first pad PA is arranged on one of the two ends of the second chip 30 in the x-direction that is closer to the third resin side surface 110c. In other words, the first pad PA is arranged closer to the drain pad PD in the x-direction than the second pad PB and the third pad PC are.

The third pad PC is arranged on one of the two ends of the second chip 30 in the x-direction that is closer to the fourth resin side surface 110d. In other words, the third pad PC is arranged closer to the gate pad PG in the x-direction than the first pad PA and the second pad PB are. As viewed in the y-direction, the third pad PC is arranged to overlap the gate pad PG.

The second pad PB is arranged at the center of the second chip 30 in the x-direction. The first pad PA and the second pad PB are located closer to the third resin side surface 110c than the sense source pad PSS and the gate pad PG are. In other words, the first pad PA and the second pad PB are offset toward the third resin side surface 110c from the sense source pad PSS and the gate pad PG as viewed in the y-direction.

The semiconductor module 100 includes a connection member 120 electrically connecting the first chip 20 and the second chip 30. The connection member 120 includes a conductive material. The conductive material may be, for example, Cu, Al, a CuAl alloy, or the like. In the present embodiment, the connection member 120 is formed of a metal plate formed from a conductive material. The connection member 120 is arranged on the first chip 20 and the second chip 30. Thus, the connection member 120 extends over the first chip 20 and the second chip 30. The connection member 120 is encapsulated by the second encapsulation portion 112 (encapsulation resin 110). In the present embodiment, the connection member 120 includes a first connection member 121, a second connection member 122, a third connection member 123, and a fourth connection member 124.

The first connection member 121 electrically connects the drain pad PD of the first chip 20 and the first pad PA of the second chip 30. In the present embodiment, the first connection member 121 is connected to the entire surface of the drain pad PD. The first connection member 121 is bonded to the drain pad PD and the first pad PA by ultrasonic bonding or the like.

The second connection member 122 electrically connects the main source pad PSM of the first chip 20 and the second pad PB of the second chip 30. In plan view, the second connection member 122 is formed so as to avoid the sense source pad PSS. The second connection member 122 is bonded to the main source pad PSM and the second pad PB.

The third connection member 123 electrically connects the gate pad PG of the first chip 20 and the third pad PC of the second chip 30. The third connection member 123 is bonded to the gate pad PG and the third pad PC.

The fourth connection member 124 is electrically connected to the sense source pad PSS of the first chip 20. The fourth connection member 124 is bonded to the sense source pad PSS. The fourth connection member 124 may be integrated with the second connection member 122.

As shown in FIG. 12, the semiconductor module 100 includes a drain terminal 131, a main source terminal 132, a sense source terminal 133, and a gate terminal 134. The terminals 131 to 134 are formed on the resin front surface 110s. In plan view, the terminals 131 to 134 are arranged separately from each other.

In plan view, the drain terminal 131 is arranged to overlap the drain pad PD of the first chip 20. In other words, in plan view, the drain terminal 131 is arranged to overlap the first connection member 121 (refer to FIG. 11). The drain terminal 131 is electrically connected to the drain pad PD by the first connection member 121. In an example, a first opening 113 is formed in the encapsulation resin 110 at a position where the drain terminal 131 is formed to expose the first connection member 121. The drain terminal 131 fills the first opening 113 and includes a portion extending out from the first opening 113 to the resin front surface 110s.

In plan view, the main source terminal 132 is arranged to overlap the main source pad PSM of the first chip 20. In other words, in plan view, the main source terminal 132 is arranged to overlap the second connection member 122. The main source terminal 132 is electrically connected to the main source pad PSM by the second connection member 122. In an example, as shown in FIGS. 12 and 13, a second opening 114 is formed in the encapsulation resin 110 at a position where the main source terminal 132 is formed to expose the second connection member 122. The main source terminal 132 fills the second opening 114 and includes a portion extending out from the second opening 114 to the resin front surface 110s.

In plan view, the sense source terminal 133 is arranged to overlap the sense source pad PSS of the first chip 20. The sense source terminal 133 is electrically connected to the sense source pad PSS. In an example, as shown in FIGS. 12 and 13, a third opening 115 is formed in the encapsulation resin 110 at a position where the sense source terminal 133 is formed to expose the fourth connection member 124. The third opening 115 is separate from the second opening 114 in the y-direction. The sense source terminal 133 fills the third opening 115 and includes a portion extending out from the third opening 115 to the resin front surface 110s.

In plan view, the gate terminal 134 is arranged to overlap the gate pad PG of the first chip 20. The gate terminal 134 is electrically connected to the gate pad PG by the third connection member 123. In an example, as show in FIGS. 12 and 13, a fourth opening 116 is formed in the encapsulation resin 110 at a position where the gate terminal 134 is formed to expose the third connection member 123. The gate terminal 134 fills the fourth opening 116 and includes a portion extending out from the fourth opening 116 to the resin front surface 110s.

A front insulation layer 135 is formed on the resin front surface 110s. The front insulation layer 135 is formed to cover peripheral edges of each of the terminals 131 to 134. In other words, the terminals 131 to 134 each include a portion exposed from the front insulation layer 135.

### Detailed Structure of Second Chip

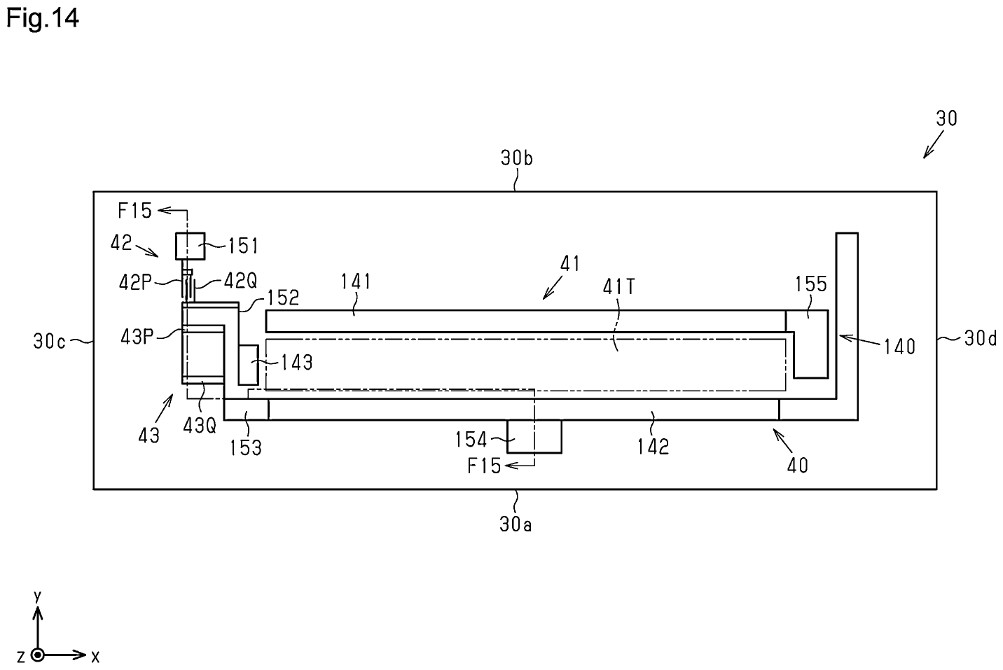

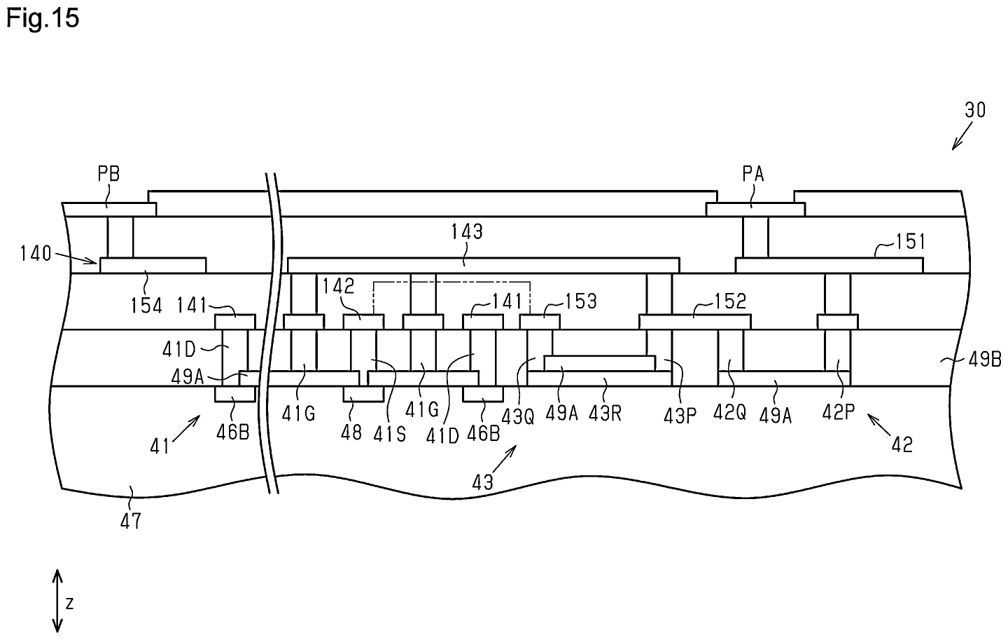

The structure of the second chip 30 will now be described in detail with reference to FIGS. 14 and 15.

FIG. 14 is a plan view of the second chip 30 mainly showing an example of the planar structure of the active clamp circuit 40. FIG. 15 is a cross-sectional view of the second chip 30 taken along line F15-F15 in FIG. 14, mainly showing the schematic cross-sectional structure of the clamp transistor 41, the clamp capacitor 42, and the pull-down resistor 43 and the internal connection configuration of the active clamp circuit 40. In FIG. 14, to facilitate illustration, the clamp transistor 41, the clamp capacitor 42, and the pull-down resistor 43 are indicated by solid lines.

As shown in FIG. 14, the second chip 30 includes a first chip side surface 30a, a second chip side surface 30b, a third chip side surface 30c, and a fourth chip side surface 30d. The first chip side surface 30a and the second chip side surface 30b define two end surfaces of the second chip 30 in the short-side direction (y-direction). The third chip side surface 30c and the fourth chip side surface 30d define two end surfaces of the second chip 30 in the long-side direction (x-direction). The first chip side surface 30a faces the same direction as the first resin side surface 110a (refer to FIG. 12). The second chip side surface 30b faces the same direction as the second resin side surface 110b (refer to FIG. 12). The third chip side surface 30c faces the same direction as the third resin side surface 110c (refer to FIG. 12). The fourth chip side surface 30d faces the same direction as the fourth resin side surface 110d (refer to FIG. 12).

The clamp transistor 41, the clamp capacitor 42, and the pull-down resistor 43 of the active clamp circuit 40 are formed in different positions in plan view. In the present embodiment, the clamp capacitor 42 and the pull-down resistor 43 are located closer to the third chip side surface 30c than the clamp transistor 41 is. The pull-down resistor 43 is located closer to the first chip side surface 30a than the clamp capacitor 42 is.

The clamp transistor 41 includes an active region 41T in which a transistor is formed. In plan view, the active region 41T is rectangular and has a long-side direction and a short-side direction. In the present embodiment, the active region 41T is rectangular so that the long-side direction is aligned with the x-direction and the short-side direction is aligned with the y-direction. The long-side direction of the active region 41T is aligned with the long-side direction of the second chip 30. In addition, in plan view, in the first chip 20 (refer to FIG. 12), the long-side direction is aligned with the y-direction, and the short-side direction is aligned with the x-direction. Thus, the long-side direction of the active region 41T is orthogonal to the long-side direction of the first chip 20.

As shown in FIG. 15, in the present embodiment, the clamp transistor 41 is a MOSFET having a lateral structure. Hence, the drain electrode 41D, the source electrode 41S, and the gate electrode 41G of the clamp transistor 41 are exposed from a surface of the intermediate insulation film 49B. In the present embodiment, a drain region 46B is formed in a surface of the base region 46 and is separated from the source region 48. The drain electrode 41D is in contact with the drain region 46B. The source electrode 41S is in contact with the source region 48. The clamp transistor 41 of the present embodiment differs from the clamp transistor 41 of the first embodiment in that instead of a gate trench, the gate electrode 41G is formed on the insulation film 49A formed on the base region 46. The gate electrode 41G is covered by the intermediate insulation film 49B.

As shown in FIG. 14, in the present embodiment, the first electrode 42P and the second electrode 42Q of the clamp capacitor 42 are formed of multiple wires.

The first electrode 42P includes multiple first wires (in the present embodiment, two) extending in the y-direction and a second wire extending in the x-direction. The two first wires are spaced apart from each other in the x-direction. The second wire connects ends of the two first wires located closer to the second chip side surface 30b in the x-direction.

The second electrode 42Q includes multiple third wires (in the present embodiment, two) extending in the y-direction and a fourth wire extending in the x-direction. The two third wires are spaced apart from each other in the x-direction. The third wires are opposed to the first wires of the first electrode 42P in the x-direction. The first wires and the third wires are alternately arranged in the x-direction. The fourth wire is located closer to the first chip side surface 30a in the y-direction than the second wire of the first electrode 42P is. The fourth wire connects ends of the two third wires located closer to the first chip side surface 30a in the x-direction. As shown in FIG. 15, in the same manner as the first embodiment, the clamp capacitor 42 is formed on the insulation film 49A and covered by the intermediate insulation film 49B.

As shown in FIGS. 14 and 15, the pull-down resistor 43 is configured in the same manner as the pull-down resistor 43 of the first embodiment.

As shown in FIG. 15, in the present embodiment, the clamp transistor 41, the clamp capacitor 42, and the pull-down resistor 43 are formed at the same position in the thickness-wise direction (z-direction) of the semiconductor substrate 44 (refer to FIG. 6).

As shown in FIG. 15, the clamp transistor 41, the clamp capacitor 42, and the pull-down resistor 43 are electrically connected to each other by an interconnect layer 140. The interconnect layer 140 includes a clamp drain interconnect 141, a clamp source interconnect 142, and a clamp gate interconnect 143.

The clamp drain interconnect 141 is electrically connected to multiple drain electrodes 41D of the clamp transistor 41. In FIG. 14, for the sake of convenience, the clamp drain interconnect 141 is located closer to the second chip side surface 30b than the active region 41T is. In plan view, the clamp drain interconnect 141 has the form of a strip elongated in the x-direction. The shown clamp drain interconnect 141 is a portion that joins multiple clamp drain interconnects 141 (refer to FIG. 15) formed on the active region 41T.

The clamp source interconnect 142 is electrically connected to multiple source electrodes 41S of the clamp transistor 41. In FIG. 14, the clamp source interconnect 142 has the form of a strip elongated in the x-direction and is located closer to the first chip side surface 30a than the active region 41T is for the sake of convenience. The shown clamp source interconnect 142 is a portion that joins multiple clamp source interconnects 142 (refer to FIG. 15) formed on the active region 41T.

The clamp gate interconnect 143 is electrically connected to multiple gate electrodes 41G of the clamp transistor 41. For the sake of convenience, in FIG. 14, the clamp gate interconnect 143 has the form of a small rectangle located next to the active region 41T in the x-direction. However, the actual clamp gate interconnect 143 extends in the entire active region 41T.

As shown in FIGS. 14 and 15, the interconnect layer 140 further includes a first interconnect 151, a second interconnect 152, a third interconnect 153, a fourth interconnect 154, and a fifth interconnect 155.

The first interconnect 151 electrically connects the clamp capacitor 42 and the first pad PA (refer to FIG. 11). More specifically, the first interconnect 151 connects the second wire of the first electrode 42P in the clamp capacitor 42 and the first pad PA. Since the first pad PA is electrically connected to the drain electrode 21D of the main transistor 21 by the first connection member 121 shown in FIG. 11, the first interconnect 151 is electrically connected to the drain electrode 21D. Thus, the first electrode 42P of the clamp capacitor 42 is electrically connected to the drain electrode 21D.

The second interconnect 152 electrically connects the gate electrode 41G of the clamp transistor 41 to the clamp capacitor 42 and the pull-down resistor 43. More specifically, the second interconnect 152 electrically connects the gate electrode 41G to the fourth wire of the second electrode 42Q of the clamp capacitor 42 and the first terminal 43P of the pull-down resistor 43. In other words, the second interconnect 152 is a portion of the clamp gate interconnect 143 that is connected to the gate electrode 41G. That is, the clamp gate interconnect 143 includes the second interconnect 152.

As shown in FIG. 14, in plan view, the second interconnect 152 is located closer to the third chip side surface 30c than the active region 41T is. The second interconnect 152 is formed between the clamp capacitor 42 and the pull-down resistor 43 in the y-direction.

The third interconnect 153 electrically connects the pull-down resistor 43 and the source electrode 41S of the clamp transistor 41. More specifically, the third interconnect 153 electrically connects the second terminal 43Q of the pull-down resistor 43 and the source electrode 41S. In other words, the third interconnect 153 is a portion of the clamp source interconnect 142 that is connected to the source electrode 41S. That is, the clamp source interconnect 142 includes the third interconnect 153. In plan view, the third interconnect 153 is located closer to the first chip side surface 30a and the third chip side surface 30c than the active region 41T is.

The fourth interconnect 154 electrically connects the source electrode 41S of the clamp transistor 41 and the second pad PB. More specifically, the fourth interconnect 154 connects the clamp source interconnect 142 and the second pad PB (refer to FIG. 11). In the present embodiment, the fourth interconnect 154 is integrated with the clamp source interconnect 142. In other words, the fourth interconnect 154 is a portion of the clamp source interconnect 142. That is, the clamp source interconnect 142 includes the fourth interconnect 154. In plan view, the fourth interconnect 154 is located closer to the first chip side surface 30a than the active region 41T is. In plan view, the fourth interconnect 154 is arranged to overlap the second pad PB. The arrangement position of the fourth interconnect 154 may be changed in any manner. In an example, in plan view, the fourth interconnect 154 may be arranged to overlap the active region 41T.

The fifth interconnect 155 electrically connects the drain electrode 41D of the clamp transistor 41 and the third pad PC (refer to FIG. 11). Since the third pad PC is electrically connected to the gate electrode 21G of the main transistor 21 by the third connection member 123, the drain electrode 41D is electrically connected to the gate electrode 21G. The fifth interconnect 155 is located closer to the fourth chip side surface 30d than the active region 41T is. In plan view, the fifth interconnect 155 is arranged to overlap the third pad PC. The arrangement position of the fifth interconnect 155 may be changed in any manner. In an example, in plan view, the fifth interconnect 155 may be arranged to overlap the active region 41T.

The wires of the clamp capacitor 42, the terminals 43P and 43Q of the pull-down resistor 43, the interconnects 141 to 143, and the interconnects 151 to 155 may be formed from, for example, any conductive material including at least one of Cu, Al, an AlCu alloy, W, Ti, and TiN. The present embodiment has the same advantages as the first embodiment.

### Third Embodiment

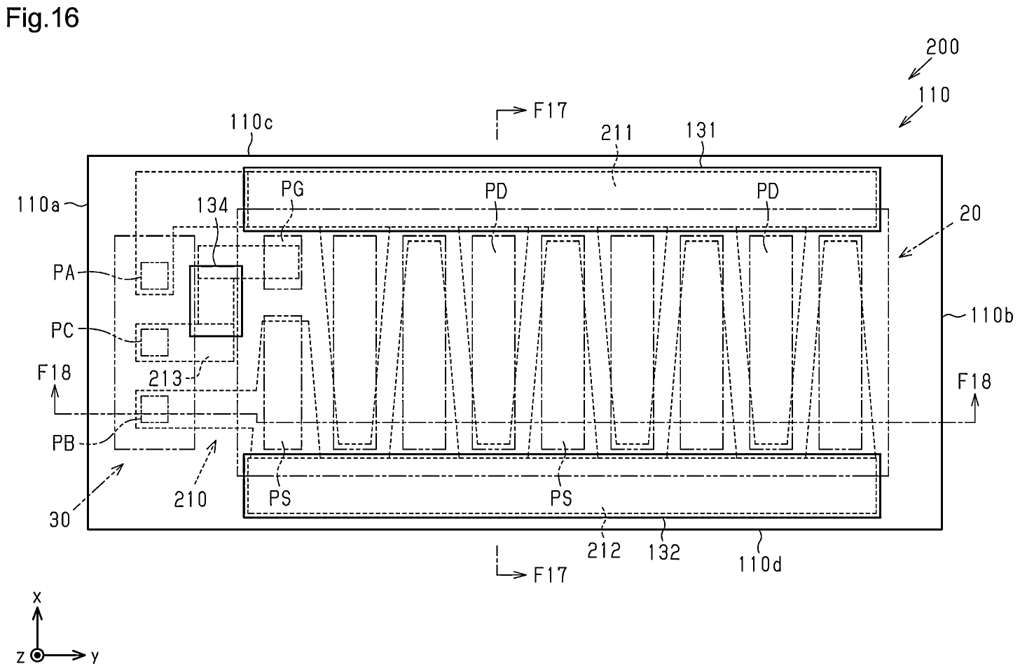

A third embodiment of a semiconductor module 200 will now be described with reference to FIGS. 16 to 18. The semiconductor module 200 of the present embodiment differs from the semiconductor module 100 of the second embodiment in mainly the configuration of the first chip 20 and the connection configuration of the first chip 20 and the second chip 30. In the description below, the same reference characters are given to those components that are the same as the corresponding components of the second embodiment. Such components will not be described in detail.

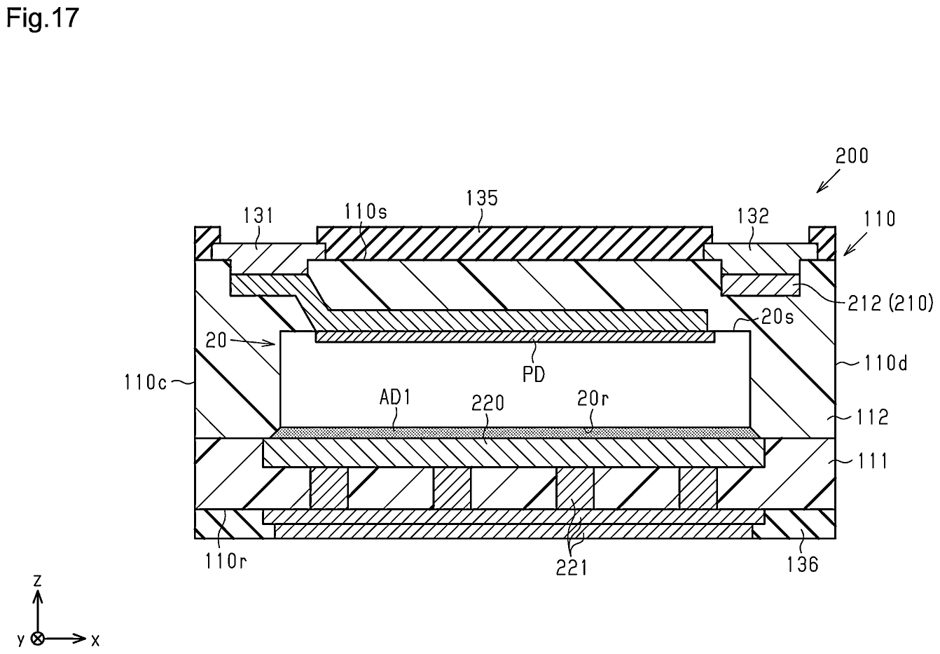

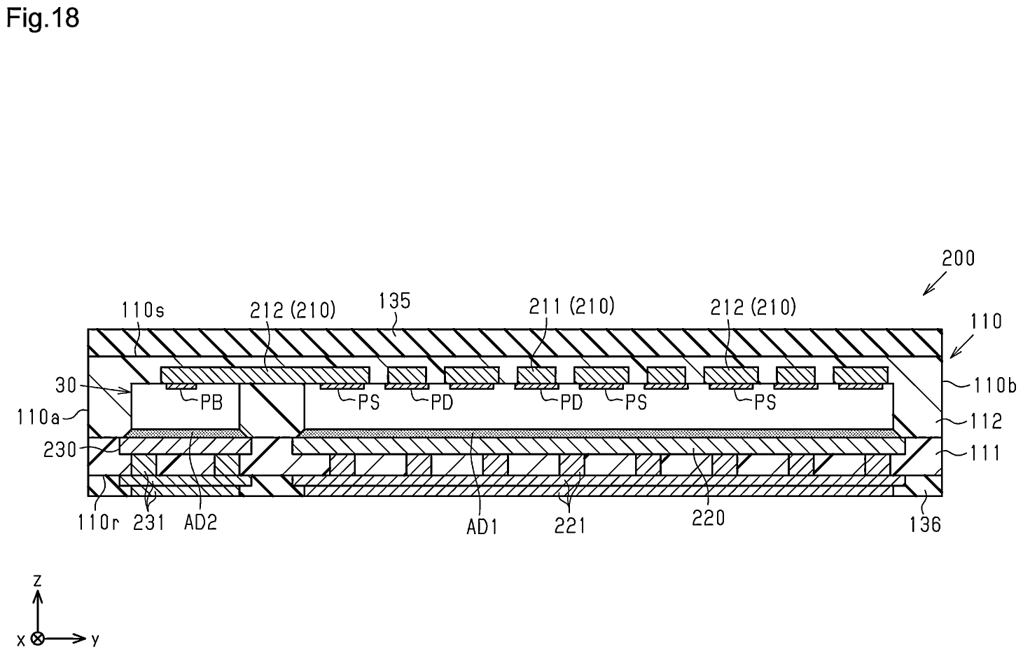

FIG. 16 is a plan view of the semiconductor module 200. FIG. 17 is a plan view of the internal structure of the semiconductor module 200 mainly showing an example of the cross-sectional structure of the first chip 20 and its surroundings. FIG. 18 is a cross-sectional view of the internal structure of the semiconductor module 200 mainly showing an example of the cross-sectional structure of the first chip 20 and the second chip 30 and their surroundings.

As shown in FIG. 16, the semiconductor module 200 includes the first chip 20, the second chip 30, and an encapsulation resin 110 encapsulating the chips 20 and 30. In FIG. 16, the chips 20 and 30, located in the encapsulation resin 110, are indicated by double-dashed lines to facilitate illustration.

In the present embodiment, the first chip 20 and the second chip 30 are aligned with each other in the short-side direction (x-direction) of the encapsulation resin 110 and are separated from each other in the long-side direction (y-direction) of the encapsulation resin 110.

The first chip 20 differs from the first chip 20 of the second embodiment in pad structure. In the present embodiment, the first chip 20 includes drain pads PD, a gate pad PG, and source pads PS. In the present embodiment, the first chip 20 does not include the sense source pad PSS of the second embodiment. The drain pads PD and the source pads PS are alternately arranged in the long-side direction (in the present embodiment, the y-direction) of the first chip 20. The gate pad PG is arranged on one of the two ends of the first chip 20 in the long-side direction that is closer to the second chip 30.

The drain terminal 131, the main source terminal 132, and the gate terminal 134 are formed in the resin front surface 110s (refer to FIG. 17). The present embodiment differs from the second embodiment in that the sense source terminal 133 is not formed on the resin front surface 110s.

As shown in FIGS. 16 and 17, the semiconductor module 200 includes a connection member 210 that connects the first chip 20 and the second chip 30. As shown in FIG. 17, the connection member 210 is arranged closer to the resin front surface 110s than the chips 20 and 30 are. The connection member 210 is encapsulated by the second encapsulation portion 112 (encapsulation resin 110). As shown in FIG. 18, the connection member 210 is partially exposed from the second encapsulation portion 112 (encapsulation resin 110) to include the drain terminal 131, the main source terminal 132, and the gate terminal 134. In the same manner as the second embodiment, the drain terminal 131, the main source terminal 132, and the gate terminal 134 are covered by the front insulation layer 135. In the same manner as the second embodiment, the drain terminal 131, the main source terminal 132, and the gate terminal 134 are partially exposed from the front insulation layer 135.

As shown in FIG. 16, the connection member 210 includes a first connection member 211, a second connection member 212, and a third connection member 213. The connection members 211 to 213 each include a first part joining the chips 20 and 30, a second part exposed from the resin front surface 110s, and a third part connecting the first part and the second part. Since the second part is located closer to the resin front surface 110s than the first part is, the third part is bent in the z-direction.

The first connection member 211 connects the drain pads PD of the first chip 20 to the first pad PA of the second chip 30. The first connection member 211 includes a portion exposed from the encapsulation resin 110 to form the drain terminal 131. In plan view, the first connection member 211 includes a comb-tooth portion joined to the drain pads PD and an extension extending toward the second chip 30 from an end of the comb-tooth portion located closer to the second chip 30. The extension is joined to the first pad PA.

The second connection member 212 connects the source pads PS of the first chip 20 and the second pad PB of the second chip 30. The second connection member 212 includes a portion exposed from the encapsulation resin 110 to form the main source terminal 132. In plan view, the second connection member 212 includes a comb-tooth portion joined to the source pads PS and an extension extending toward the second chip 30 from an end of the comb-tooth portion located closer to the second chip 30 in the y-direction. The extension is joined to the second pad PB.

The third connection member 213 connects the gate pad PG of the first chip 20 and the third pad PC of the second chip 30. The third connection member 213 includes a portion exposed from the encapsulation resin 110 and electrically connected to the gate terminal 134. In plan view, the third connection member 213 is crank-shaped so as to avoid the first connection member 211.

As shown in FIG. 18, a first die pad 220, on which the first chip 20 is mounted, and a second die pad 230, on which the second chip 30 is mounted, are arranged on the first encapsulation portion 111. The die pads 220 and 230 are formed from, for example, a metal material such as Cu, Al, or a CuAl alloy. In the present embodiment, a Cu frame is used as the die pads 220 and 230. The first encapsulation portion 111 is formed to cover side surfaces of the die pads 220 and 230. In other words, the die pads 220 and 230 are exposed from the first encapsulation portion 111 (resin back surface 110r).

The first encapsulation portion 111 includes a first heat dissipation structure 221 configured to dissipate heat from the first die pad 220 to the outside of the first encapsulation portion 111. The first heat dissipation structure 221 includes vias and a thermal pad that is formed on the resin back surface 110r. The vias connect the thermal pad and the first die pad 220.

The first encapsulation portion 111 includes a second heat dissipation structure 231 configured to dissipate heat from the second die pad 230 to the outside of the first encapsulation portion 111. The structure of the second heat dissipation structure 231 is the same as the structure of the first heat dissipation structure 221 and thus will not be described in detail.

The first chip 20 is bonded to the first die pad 220 by the first bonding material AD1. The second chip 30 is bonded to the second die pad 230 by the second bonding material AD2. Each of the bonding materials AD1 and AD2 is a conductive bonding material such as solder paste or Ag paste.

Aback insulation layer 136 is formed on the resin back surface 110r. The back insulation layer 136 is formed from a material including at least one of SiO₂ and SiN. The back insulation layer 136 is formed to cover peripheral edge of each of the heat dissipation structures 221 and 231. In other words, the heat dissipation structures 221 and 231 each include a portion exposed from the back insulation layer 136.

### Advantages

The present embodiment has the following advantages in addition to the advantages of the first embodiment.

(3-1) The first chip 20 is mounted on the first die pad 220 exposed from the resin back surface 110r of the encapsulation resin 110. The first die pad 220 is formed from a metal material.

In this structure, heat readily dissipates from the first chip 20 to the outside of the semiconductor module 200 via the first die pad 220 as compared to a structure in which the semiconductor module 200 does not include the first die pad 220. Thus, an excessive increase in the temperature of the first chip 20 is avoided.

### Fourth Embodiment

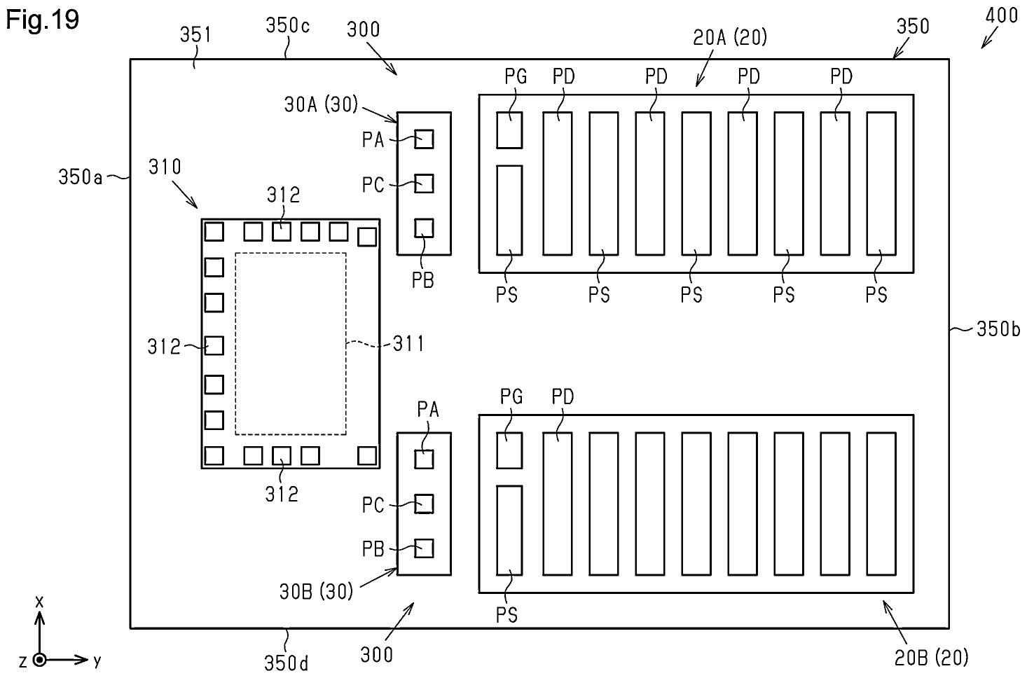

A fourth embodiment of a semiconductor module 300 and a semiconductor unit 400 will now be described with reference to FIGS. 19 to 24. The present embodiment differs from the third embodiment in mainly the number of first chips 20 and second chips 30 and addition of a third chip 310. In the description below, the same reference characters are given to those components that are the same as the corresponding components of the third embodiment. Such components will not be described in detail.

### Configuration of Semiconductor Unit

The configuration of the semiconductor unit 400 will be described with reference to FIGS. 19 to 23.

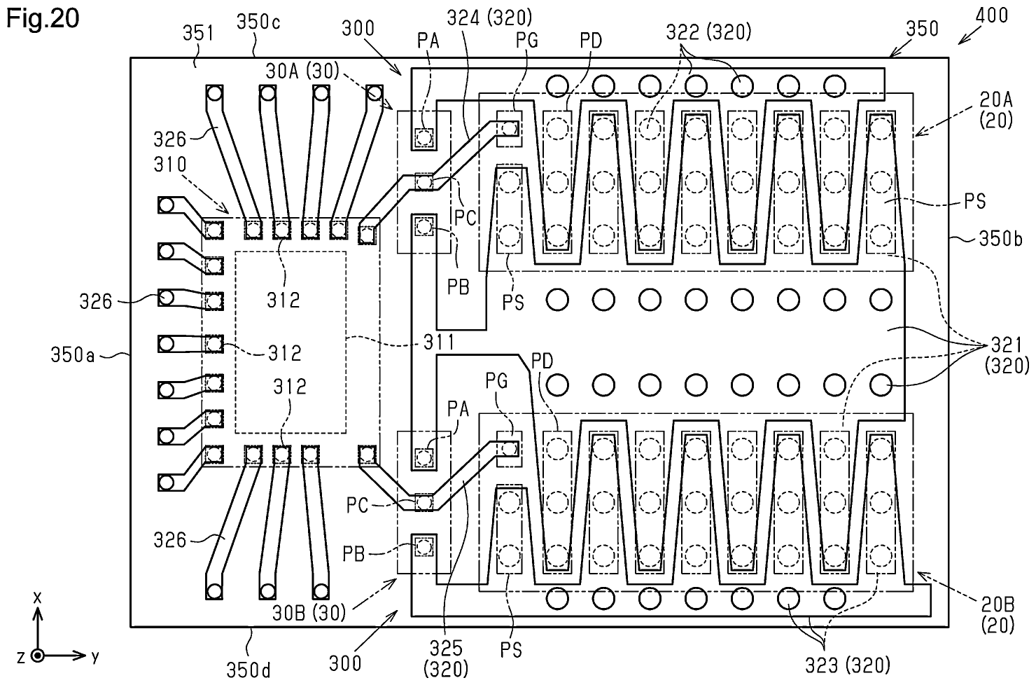

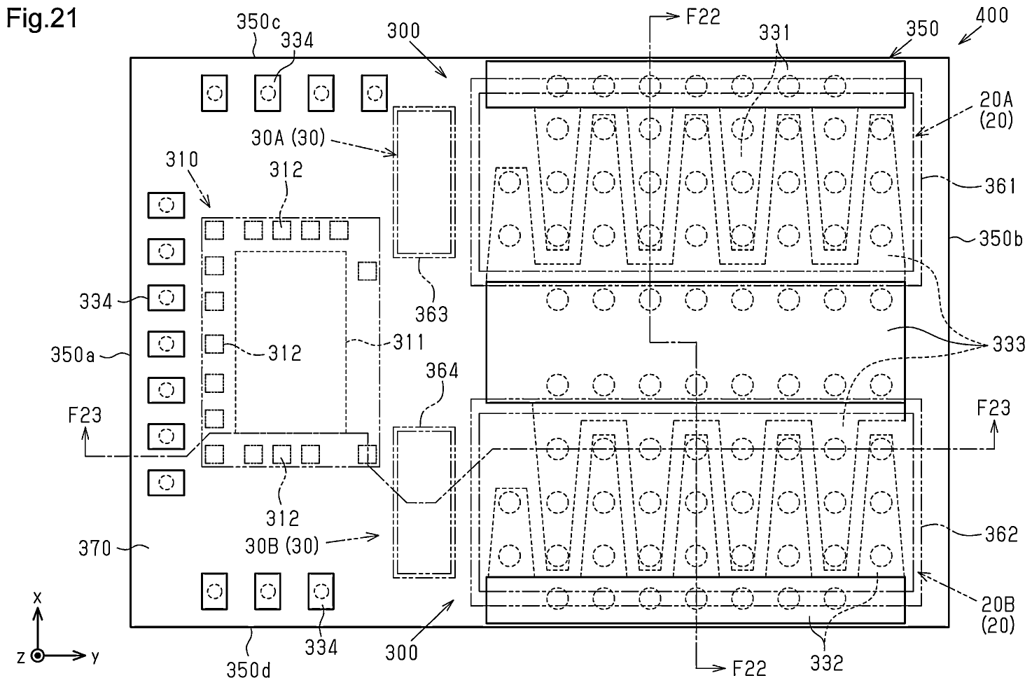

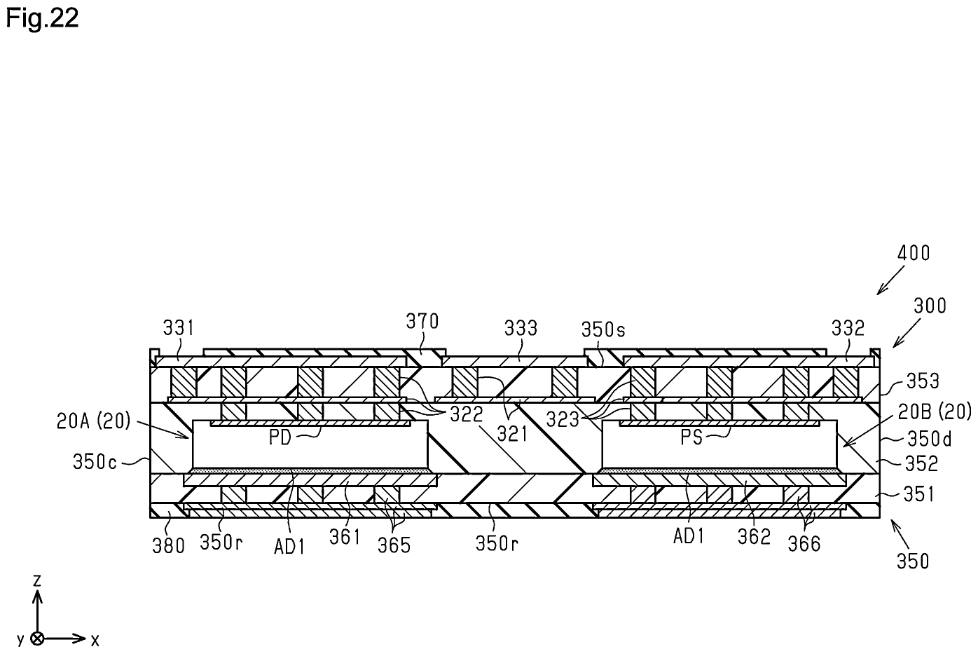

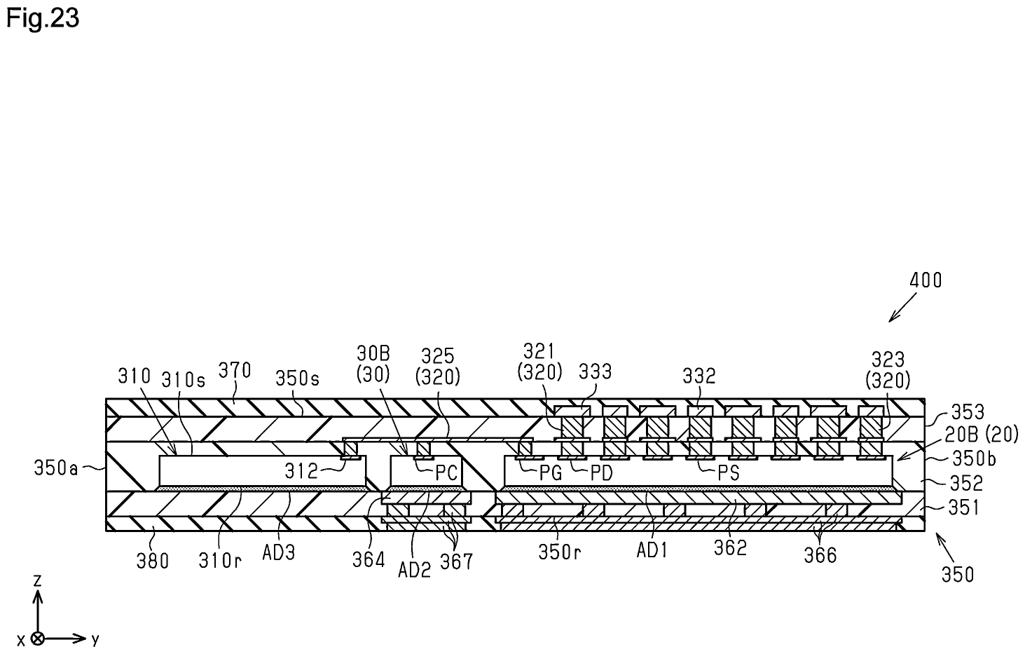

FIG. 19 is a plan view of the internal structure of the semiconductor module 300 mainly showing an example of the arrangement configuration of the first chip 20, the second chip 30, and the third chip 310, which will be described later. FIG. 20 is a plan view of the internal structure of the semiconductor module 300 mainly showing an example of the structure of an interconnect layer. FIG. 21 is a plan view of the semiconductor module 300. FIG. 22 is a cross-sectional view of an example of the cross-sectional structure of the semiconductor module 200 taken along line F22-F22 in FIG. 21 mainly showing the first chip 20 and its surroundings. FIG. 23 is a cross-sectional view of an example of the cross-sectional structure of the semiconductor module 200 taken along line F23-F23 in FIG. 22 mainly showing the third chip 310 and the first chip 20.

As shown in FIG. 19, the semiconductor unit 400 includes the semiconductor module 300 and the third chip 310. The third chip 310 is arranged separately from the first chip 20 and the second chip 30. The third chip 310 is encapsulated by an encapsulation resin 350 of the semiconductor module 300.

The present embodiment differs from the second embodiment in the structure of the semiconductor module 300. More specifically, the semiconductor module 300 includes multiple (in the present embodiment, two) first chips 20, multiple (in the present embodiment, two) second chips 30, and the encapsulation resin 350 encapsulating the first chips 20 and the second chips 30. In FIG. 19, the chips 20, 30, and 310, located in the encapsulation resin 350, are indicated by solid lines to facilitate illustration. In the description hereafter, for the sake of convenience, the two first chips 20 are separately referred to as a “first chip 20A” and a “first chip 20B.” The two second chips 30 are also separately referred to as a “second chip 30A” and a “second chip 30B.”

The semiconductor module 300 has the form of a rectangular plate. The encapsulation resin 350 defines outer surfaces of the semiconductor module 300. That is, the encapsulation resin 350 has the form of a rectangular plate. The encapsulation resin 350 includes a resin front surface 350s and a resin back surface 350r (refer to FIG. 22) that face opposite directions and first to fourth resin side surfaces 350a to 350d, which are four resin side surfaces intersecting the resin front surface 350s and the resin back surface 350r. In the present embodiment, the first to fourth resin side surfaces 350a to 350d are orthogonal to the resin front surface 350s and the resin back surface 350r. In the present embodiment, the thickness-wise direction of the encapsulation resin 350 refers to the z-direction. In the description, “plan view” includes the meaning of “view in the thickness-wise direction of the encapsulation resin 350.”

In plan view, the encapsulation resin 350 is rectangular and has a long-side direction and a short-side direction. In the present embodiment, the long-side direction of the encapsulation resin 350 is aligned with the y-direction. The short-side direction of the encapsulation resin 350 is aligned with the x-direction. In the present embodiment, the first resin side surface 350a and the second resin side surface 350b define opposite end surfaces in the y-direction. The third resin side surface 350c and the fourth resin side surface 350d define opposite end surfaces in the x-direction. The encapsulation resin 350 is formed from an insulative resin material. Such a resin material includes, for example, an epoxy resin, an acrylic resin, and a phenol resin.

The first chips 20A and 20B are aligned with each other in the long-side direction (y-direction) of the encapsulation resin 350 and are separated from each other in the short-side direction (x-direction) of the encapsulation resin 110. In plan view, the first chips 20A and 20B are off-center of the encapsulation resin 350 in the y-direction. In the present embodiment, in plan view, the first chips 20A and 20B are located closer to the second resin side surface 350b of the encapsulation resin 350 than to the first resin side surface 350a. The first chips 20A and 20B are arranged so that the long-side direction of the first chips 20A and 20B is aligned with the y-direction and the short-side direction of the first chips 20A and 20B is aligned with the x-direction. In other words, the long-side direction of each of the first chips 20A and 20B is aligned with the long-side direction of the encapsulation resin 350, and the short-side direction of each of the first chips 20A and 20B is aligned with the short-side direction of the encapsulation resin 350.

In plan view, the third chip 310 is separated from the first chips 20A and 20B in a direction orthogonal to a direction in which the first chips 20A and 20B are arranged. More specifically, the third chip 310 is located closer to the first resin side surface 350a in the y-direction than the first chips 20A and 20B are. The third chip 310 has the form of a rectangular plate. In plan view, the third chip 310 is rectangular and has a long-side direction and a short-side direction. In the present embodiment, the third chip 310 is arranged so that the long-side direction of the third chip 310 is aligned with the x-direction and the short-side direction of the third chip 310 is aligned with the y-direction. Thus, in plan view, the long-side direction of the third chip 310 is orthogonal to the long-side direction of the encapsulation resin 350 and the long-side direction of the first chips 20A and 20B, and the short-side direction of the third chip 310 is orthogonal to the short-side direction of the encapsulation resin 350 and the short-side direction of the first chips 20A and 20B. As viewed in the y-direction, the third chip 310 is arranged to partially overlap each of the first chips 20A and 20B. In the present embodiment, the third chip 310 is arranged in the center of the encapsulation resin 350 in the x-direction.

The third chip 310 includes a chip front surface 310s and a chip back surface 310r that face opposite directions in the z-direction (refer to FIG. 23). The chip front surface 310s faces the same direction as the resin front surface 350s. The chip back surface 310r faces the same direction as the resin back surface 350r.

The third chip 310 includes a semiconductor substrate, a driver circuit 311 formed on the semiconductor substrate and configured to separately drive the first chips 20A and 20B, and electrode pads 312 electrically connected to the driver circuit 311. The electrode pads 312 are exposed from the chip front surface 310s.

The second chips 30A and 30B are located closer to the first resin side surface 350a than the first chips 20A and 20B are. The second chip 30A is arranged between the third chip 310 and the first chip 20A in the y-direction. The second chip 30B is arranged between the third chip 310 and the first chip 20B in the y-direction. The second chip 30A is located next to the first chip 20A in the y-direction. The second chip 30B is located next to the first chip 20B in the y-direction.

As shown in FIG. 20, the semiconductor module 300 includes an interconnect layer 320. The interconnect layer 320 includes at least two types of interconnect layer. One type of interconnect layer includes a via extending in the z-direction and an interconnect extending in a direction orthogonal to the z-direction. The other type of interconnect layer includes only a via extending in the z-direction. The interconnect layer 320 is configured to connect the first chips 20A and 20B, the second chips 30A and 30B, and the third chip 310.

The interconnect layer 320 includes a first interconnect 321, a second interconnect 322, a third interconnect 323, a fourth interconnect 324, and a fifth interconnect 325. The interconnect layer 320 further includes driver interconnects 326 connected to the third chip 310. The interconnects 321 to 325 and the driver interconnects 326 each extend in a direction orthogonal to the z-direction without bending in the z-direction. The interconnects 321 to 325 and the driver interconnects 326 are each formed of a metal plating.

The first interconnect 321 connects the source pads PS of the first chip 20A and the drain pads PD of the first chip 20B to the second pad PB of the second chip 30A and the first pad PA of the second chip 30B. In plan view, the first interconnect 321 includes a comb-tooth portion, a first extension, and a second extension. The comb-tooth portion is electrically connected to the source pads PS of the first chip 20A and the drain pads PD of the first chip 20B by, for example, vias. The first extension extends toward the second chip 30A from an end of the comb-tooth portion located closer to the second chip 30A. The first extension is electrically connected to the second pad PB of the second chip 30A by, for example, a via. The second extension extends toward the second chip 30B from an end of the comb-tooth portion located closer to the second chip 30B. The second extension is electrically connected to the first pad PA of the second chip 30B by, for example, a via.

The second interconnect 322 connects the drain pads PD of the first chip 20A and the first pad PA of the second chip 30A. The second interconnect 322 includes a portion located closer to the third resin side surface 350c than the first interconnect 321 is. In plan view, the second interconnect 322 includes a comb-tooth portion electrically connected to the drain pads PD and an extension extending toward the second chip 30A from an end of the comb-tooth portion located closer to the second chip 30A. The comb-tooth portion is electrically connected to each of the drain pads PD by, for example, vias. The extension is electrically connected to the first pad PA by, for example, a via.

The third interconnect 323 connects the source pads PS of the first chip 20B and the second pad PB of the second chip 30B. The third interconnect 323 includes a portion located closer to the fourth resin side surface 350d than the first interconnect 321 is. The third interconnect 323 includes a comb-tooth portion and an extension. The comb-tooth portion is electrically connected to the source pads PS by, for example, vias. The extension is electrically connected to the second pad PB by, for example, a via.

The fourth interconnect 324 connects the gate pad PG of the first chip 20A, the third pad PC of the second chip 30A, and one of the electrode pads 312 of the third chip 310. The fourth interconnect 324 is electrically connected to the gate pad PG and the electrode pad 312 by, for example, vias.

The fifth interconnect 325 connects the gate pad PG of the first chip 20B, the third pad PC of the second chip 30B, and one of the electrode pads 312 of the third chip 310. The fifth interconnect 325 is electrically connected to the gate pad PG and the electrode pad 312 by, for example, vias. The fourth interconnect 324 and the fifth interconnect 325 each correspond to a “control connection member.”

The driver interconnects 326 are respectively connected to the electrode pads 312 of the third chip 310. In plan view, each of the driver interconnects 326 extends outward beyond the third chip 310 toward one of the first resin side surface 350a, the third resin side surface 350c, and the fourth resin side surface 350d.

As shown in FIG. 21, the semiconductor module 200 includes a drain terminal 331, a source terminal 332, an output terminal 333, and driver terminals 334. The terminals 331 to 334 are formed on the resin front surface 350s. In FIG. 21, portions of the drain terminal 331, the source terminal 332, and the output terminal 333 that are not exposed from the encapsulation resin 350 are indicated by broken lines.

The drain terminal 331, the source terminal 332, and the output terminal 333 are aligned with each other in the y-direction and separated from each other in the x-direction. The drain terminal 331, the source terminal 332, and the output terminal 333 are located closer to the second resin side surface 350b than to the first resin side surface 350a in the y-direction. In plan view, the drain terminal 331 is arranged to overlap the second interconnect 322 (refer to FIG. 20), the source terminal 332 is arranged to overlap the third interconnect 323 (refer to FIG. 20), and the output terminal 333 is arranged to overlap the first interconnect 321 (refer to FIG. 20).

The driver terminals 334 are located closer to the first resin side surface 350a than to the second resin side surface 350b in the y-direction. In plan view, the driver terminals 334 are arranged in a line along each of the first resin side surface 350a, the third resin side surface 350c, and the fourth resin side surface 350d.

The drain terminal 331 is electrically connected to the drain electrode 21D (refer to FIG. 20) of the main transistor 21 in the first chip 20A. In plan view, the drain terminal 331 is shaped in the same manner as the comb-tooth portion of the second interconnect 322. The drain terminal 331 is electrically connected to the second interconnect 322.

The source terminal 332 is electrically connected to the source electrode 21S (refer to FIG. 20) of the main transistor 21 in the first chip 20B. In plan view, the source terminal 332 is shaped in the same manner as the comb-tooth portion of the third interconnect 323. The source terminal 332 is electrically connected to the third interconnect 323.

The output terminal 333 is electrically connected to the source electrode 21S (refer to FIG. 20) of the main transistor 21 in the first chip 20A and the drain electrode 21D (refer to FIG. 20) of the main transistor 21 in the first chip 20B. The output terminal 333 is electrically connected to the first interconnect 321.

The drain terminal 331, the source terminal 332, and the output terminal 333 are formed on the resin front surface 350s (refer to FIG. 22) and covered by a front insulation layer 370 so that the drain terminal 331, the source terminal 332, and the output terminal 333 are partially exposed from the front insulation layer 370. The portion of each of the drain terminal 331, the source terminal 332, and the output terminal 333 exposed from the front insulation layer 370 is rectangular in plan view so that the long-side direction is aligned with the y-direction and the short-side direction is aligned with the x-direction. The front insulation layer 370 is formed from a material including, for example, SiO₂ or SiN.

The driver terminals 334 are electrically connected to the driver circuit 311. The driver terminals 334 are electrically connected to the respective driver interconnects 326. More specifically, each driver terminal 334 is connected to a second via of the driver interconnect 326.

As shown in FIGS. 22 and 23, the encapsulation resin 350 includes a first encapsulation portion 351, a second encapsulation portion 352, and a third encapsulation portion 353. The encapsulation portions 351 to 353 are formed from, for example, the same material.

The first encapsulation portion 351 is a support member that supports the chips 20A, 20B, 30A, 30B, and 310. The chips 20A, 20B, 30A, 30B, and 310 are bonded to the first encapsulation portion 351 by, for example, bonding materials AD1 to AD3. The first encapsulation portion 351 includes the resin back surface 350r.

A first die pad 361 on which the first chip 20A is mounted, a second die pad 362 on which the first chip 20B is mounted, a third die pad 363 on which the second chip 30A is mounted, and a fourth die pad 364 on which the second chip 30B is mounted are formed in the first encapsulation portion 351. Although not shown, a fifth pad corresponding to the third chip 310 may be formed.

The first encapsulation portion 351 includes a first heat dissipation structure 365 configured to dissipate heat from the first die pad 361 to the outside of the encapsulation resin 350 and a second heat dissipation structure 366 configured to dissipate heat from the second die pad 362 to the outside of the encapsulation resin 350. The first encapsulation portion 351 further includes a third heat dissipation structure (not shown) configured to dissipate heat from the third die pad 363 to the outside of the encapsulation resin 350 and a fourth heat dissipation structure 367 configured to dissipate heat from the fourth die pad 364 to the outside of the encapsulation resin 350.

The first heat dissipation structure 365 includes vias formed in portions overlapping the first die pad 361 in plan view and a thermal pad formed on the resin back surface 350r. The vias connect the first die pad 361 and the thermal pad. The structure of each of the second heat dissipation structure 366 and the fourth heat dissipation structure 367 is the same as that of the first heat dissipation structure 365 and thus will not be described in detail. The die pads 361 and 362 and the heat dissipation structures 365, 366, and 367 are formed from, for example, the same material as the interconnect layer 320.

The resin back surface 350r is covered by a back insulation layer 380, which covers the peripheral edge of each thermal pad of the heat dissipation structures 365, 366, and 367. In other words, the thermal pad is exposed from the back insulation layer 380.

The third chip 310 is mounted on the first encapsulation portion 351. More specifically, the third chip 310 is bonded to the first encapsulation portion 351 by the third bonding material AD3. The third bonding material AD3 may be a conductive bonding material or an insulative bonding material. Thus, the third chip 310 is directly mounted on the first encapsulation portion 351 without being mounted on a die pad.

The second encapsulation portion 352 encapsulates the chips 20A, 20B, 30A, 30B, and 310 in cooperation with the first encapsulation portion 351.

The third encapsulation portion 353 is arranged on the second encapsulation portion 352. The third encapsulation portion 353 includes the resin front surface 350s. The drain terminal 331, the source terminal 332, the output terminal 333, and the driver terminals 334 are formed on the third encapsulation portion 353.

The interconnect layer 320 is formed in the second encapsulation portion 352 and the third encapsulation portion 353.

As shown in FIG. 22, in the interconnect layer 320, the second interconnect 322 and the third interconnect 323 (refer to FIG. 20) are formed as follows. The interconnect layer 320 includes first vias extending in the z-direction through portions of the second encapsulation portion 352 that cover the first chips 20A and 20B. The interconnect layer 320 includes interconnects formed on the second encapsulation portion 352. The interconnects are covered by the third encapsulation portion 353. The interconnect layer 320 includes second vias extending in the z-direction through the third encapsulation portion 353. In the interconnect layer 320, the second interconnect 322 and the third interconnect 323 include the vias extending in the z-direction through portions of the second encapsulation portion 352 that cover the first chips 20A and 20B and the vias extending in the z-direction through the third encapsulation portion 353.

As shown in FIG. 23, in the interconnect layer 320, the fourth interconnect 324 and the fifth interconnect 325 (refer to FIG. 20) are formed as follows. The interconnect layer 320 includes first vias extending in the z-direction through portions of the second encapsulation portion 352 that cover the first chips 20A and 20B. The interconnect layer 320 includes interconnects formed on the second encapsulation portion 352. The interconnects are covered by the third encapsulation portion 353. The interconnect layer 320 includes second vias extending in the z-direction through portions of the second encapsulation portion 352 that cover the third chip 310.

### Circuit Configuration of Semiconductor Unit

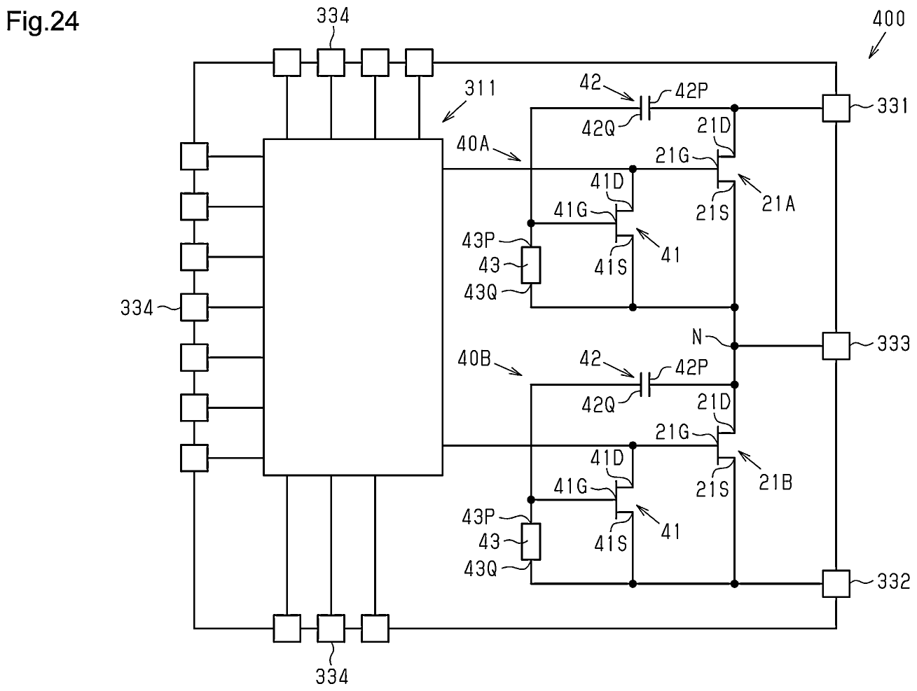

The schematic circuit configuration of the semiconductor unit 400 will now be described with reference to FIG. 24. To facilitate illustration, the circuit configuration of the driver circuit 311 is not shown in detail. In the description hereafter, the main transistor 21 of the first chip 20A is referred to as a “main transistor 21A,” and the main transistor 21 of the first chip 20B is referred to as a “main transistor 21B.” The active clamp circuit 40 of the first chip 20A is referred to as an “active clamp circuit 40A,” and the active clamp circuit 40 of the first chip 20B is referred to as an “active clamp circuit 40B.”

As shown in FIG. 24, in the same manner as the first embodiment, the main transistor 21A is electrically connected to the active clamp circuit 40A, and the main transistor 21B is electrically connected to the active clamp circuit 40B.

The drain electrode 21D of the main transistor 21A is connected to the drain terminal 331. The source electrode 21S of the main transistor 21B is connected to the source terminal 332.

The source electrode 21S of the main transistor 21A is connected to the drain electrode 21D of the main transistor 21B. The output terminal 333 is connected to a node N located between the source electrode 21S of the main transistor 21A and the drain electrode 21D of the main transistor 21B.

The gate electrode 21G of each of the main transistors 21A and 21B is connected to the driver circuit 311. The driver circuit 311 is connected to the driver terminals 334. The source electrode 21S of each of the main transistors 21A and 21B may be connected to the driver circuit 311.

In the semiconductor unit 400, when the driver terminals 334 receive a control signal for driving the main transistors 21A and 21B from an external device, the driver circuit 311 generates a drive signal for driving the main transistors 21A and 21B in accordance with the control signal, which is input to the driver circuit 311 through the driver terminals 334. The driver circuit 311 transmits the drive signal to the gate electrodes 21G of the main transistors 21A and 21B. The main transistors 21A and 21B are turned on and off based on the drive signal input to the gate electrodes 21G in a complementary manner.

### Advantages

The fourth embodiment has the following advantages in addition to the advantages of the first embodiment.

(4-1) The semiconductor unit 400 includes the first chips 20A and 20B, the second chips 30A and 30B, the third chip 310, and the encapsulation resin 350 encapsulating the first chips 20A and 20B, the second chips 30A and 30B, and the third chip 310.

In this structure, the main transistors 21 of the first chips 20A and 20B are electrically connected to the driver circuit 311 of the third chip 310 within the semiconductor unit 400. Thus, the conductive path from the main transistors 21 of the first chips 20A and 20B to the driver circuit 311 are shortened as compared to a structure in which the main transistors 21 of the first chips 20A and 20B are electrically connected to the driver circuit 311 on a circuit substrate arranged outside the semiconductor unit 400. As a result, parasitic impedance and parasitic inductance caused by the length of the conductive paths are reduced.

(4-2) In plan view, the third chip 310 is separated from the first chips 20A and 20B in a direction orthogonal to the arrangement direction of the first chips 20A and 20B.

This structure limits variations between the first chip 20A and the first chip 20B in the length of the conductive path extending from the gate electrode 21G of the main transistor 21 to the driver circuit 311 as compared to a structure in which the third chip 310 is located next to one of the first chips 20A and 20B in the arrangement direction of the first chips 20A and 20B.

### Modified Examples

The embodiments described above may be modified as follows. The embodiments described above and the modified examples described below can be combined as long as the combined modifications remain technically consistent with each other.

### Modified Examples of First Chip

In the first embodiment, the drain pad PD1, the source pad PS1, and the gate pad PG1 of the main transistor 21 may be changed to the drain pads PD, the source pads PS, and the gate pad PG of the main transistor 21 in the third and fourth embodiments. In the second embodiment, the pad configuration of the main transistor 21 may be changed to the pad configuration of the main transistor 21 in the third and fourth embodiments.

In each embodiment, a portion of the active clamp circuit 40 may be formed on the first chip 20. In an example, the clamp transistor 41 of the active clamp circuit 40 is formed on the first chip 20. In an example, the clamp capacitor 42 of the active clamp circuit 40 is formed on the first chip 20. In an example, the pull-down resistor 43 of the active clamp circuit 40 is formed on the first chip 20. In an example, the clamp transistor 41 and the clamp capacitor 42 are formed on the first chip 20. In an example, the clamp transistor 41 and the pull-down resistor 43 are formed on the first chip 20. In an example, the clamp capacitor 42 and the pull-down resistor 43 are formed on the first chip 20.

In each embodiment, the material forming the main drift layer (electron transit layer 24) of the first chip 20 may be changed in any manner as long as the material forming the main drift layer differs from the material forming the sub drift layer (drift layer 45) of the second chip 30. In an example, the main drift layer may be formed as a drift layer formed from a material including Si. In this case, the sub drift layer is formed from a material that differs from the material including Si (e.g., material including GaN).

### Modified Examples of Second Chip

In each embodiment, the configuration of the pull-down resistor 43 may be changed in any manner.

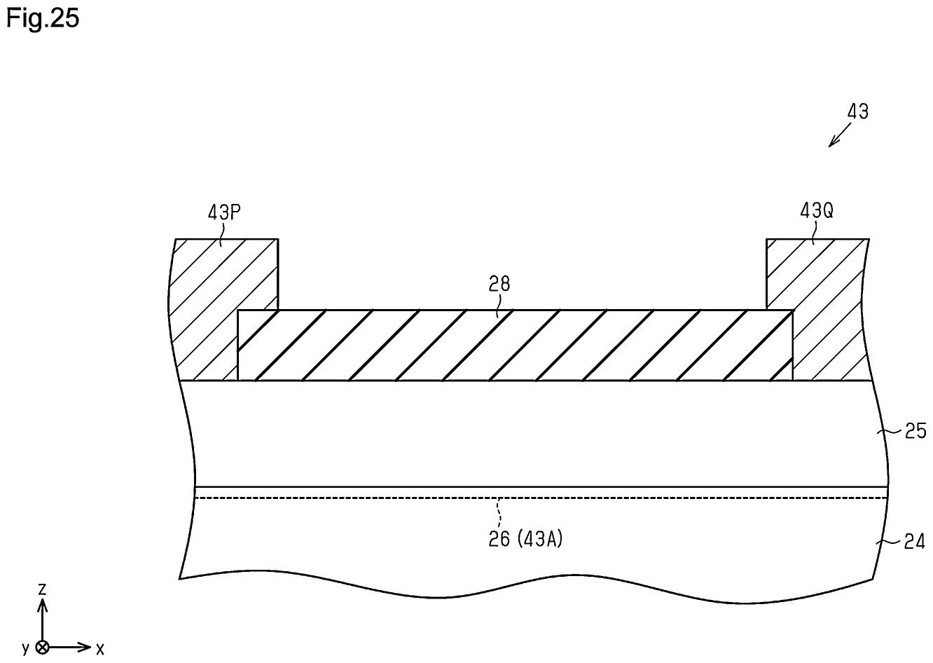

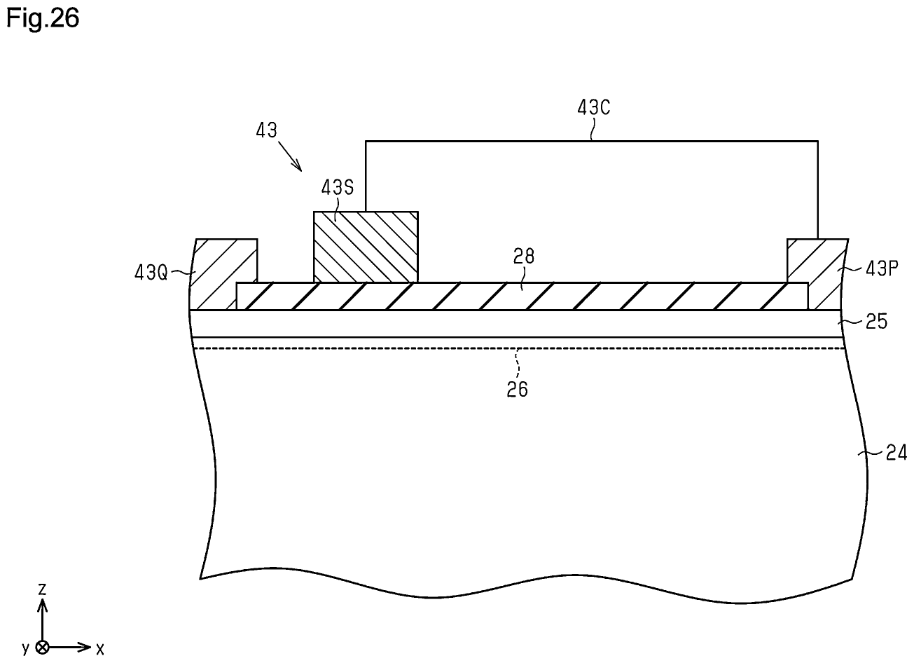

In an example, when the main drift layer of the second chip 30 includes the electron transit layer 24 formed of GaN, the pull-down resistor 43 may be changed as in a first modified example shown in FIG. 25 or a second modified example shown in FIG. 26.

As shown in FIG. 25, the pull-down resistor 43 of the first modified example includes a serpentine connection path 43A. In the present embodiment, the connection path 43A is formed of the 2DEG 26. In other words, the 2DEG 26 of the pull-down resistor 43 is formed in a serpentine manner in plan view. Thus, the connection path 43A includes a serpentine portion formed in a serpentine manner. Thus, the pull-down resistor 43 includes a resistance component of the serpentine portion. The resistance component of the serpentine portion is set in accordance with the length and width of the serpentine portion. The length and width of the serpentine portion are each set in accordance with, for example, a desired resistance of the pull-down resistor 43.

The first terminal 43P and the second terminal 43Q of the pull-down resistor 43 define two ends of the serpentine portion. The first terminal 43P is electrically connected to an end of the connection path 43A located toward the clamp capacitor 42. The second terminal 43Q is electrically connected to an end of the connection path 43A located toward the clamp transistor 41. The first terminal 43P and the second terminal 43Q are electrically connected to each other by the connection path 43A.

As shown in FIG. 25, the first terminal 43P and the second terminal 43Q are formed on the electron supply layer 25. More specifically, the first terminal 43P and the second terminal 43Q are formed on the electron supply layer 25 and are in ohmic contact with the electron supply layer 25.

As shown in FIG. 26, in the second modified example, the pull-down resistor 43 is configured by a normally-on transistor and includes an on-resistance of the normally-on transistor. More specifically, in the same manner as the main transistor 21 in the embodiments, the pull-down resistor 43 includes the electron transit layer 24, the electron supply layer 25, and the passivation layer 28. However, the pull-down resistor 43 does not include the gate layer 27, which differs from the main transistor 21 in the embodiments. The pull-down resistor 43 includes the first terminal 43P corresponding to a drain electrode, the second terminal 43Q corresponding to a source electrode, a third terminal 43S corresponding to a gate electrode, and a connection path (not shown) electrically connecting the first terminal 43P and the second terminal 43Q. The connection path is formed of the 2DEG 26 and is formed in a serpentine manner in plan view. The third terminal 43S is formed on the passivation layer 28. The third terminal 43S is arranged toward the second terminal 43Q.

The pull-down resistor 43 includes a wire 43C connecting the first terminal 43P and the third terminal 43S. The wire 43C may be formed from, for example, any conductive material including at least one of Cu, Al, an AlCu alloy, W, Ti, and TiN.

In the first embodiment, instead of the pull-down resistor 43, the clamp capacitor 42 may overlap the pad PG2 of the second chip 30 in plan view. In this case, the clamp capacitor 42 is arranged closer to the drift layer 45 than the pad PG2 is.

In the first embodiment, the clamp capacitor 42 and the pull-down resistor 43 may overlap the pad PG2 of the second chip 30 in plan view. In this case, the clamp capacitor 42 and the pull-down resistor 43 are arranged closer to the drift layer 45 than the pad PG2 is.

In the first embodiment, the clamp capacitor 42 and the pull-down resistor 43 may be arranged at a position differing from the pad PG2 of the second chip 30 in plan view.

### Circuit Configuration of Active Clamp Circuit in Modified Examples

In each embodiment, the circuit configuration of the active clamp circuit 40 may be changed in any manner. In an example, the active clamp circuit 40 may be changed as in first to third modified examples described below.

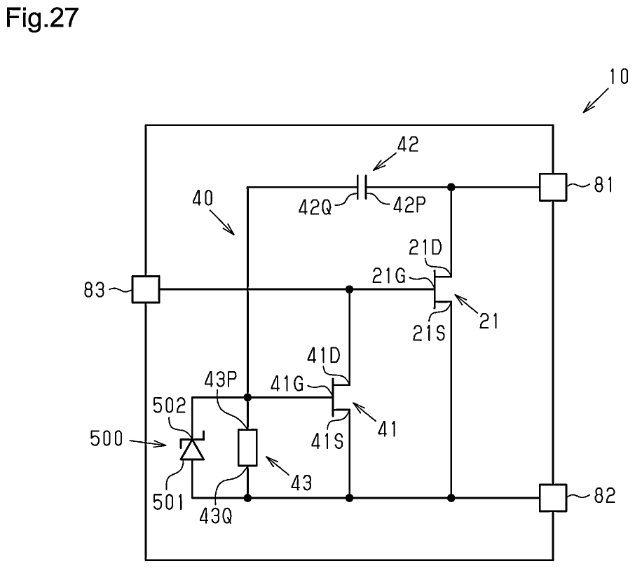

FIG. 27 shows the circuit configuration of the active clamp circuit 40 in the first modified example.

As shown in FIG. 27, in the first modified example, the active clamp circuit 40 further includes a protective diode 500 connected between the source electrode 41S and the gate electrode 41G of the clamp transistor 41. The protective diode 500 includes, for example, a Zener diode. The protective diode 500 includes an anode electrode 501 electrically connected to the source electrode 41S and a cathode electrode 502 electrically connected to the gate electrode 41G. The protective diode 500 is configured to inhibit application of a voltage higher than the gate-source rated voltage to the gate electrode 41G of the clamp transistor 41. Thus, the gate-source voltage of the clamp transistor 41 is less likely to increase excessively.

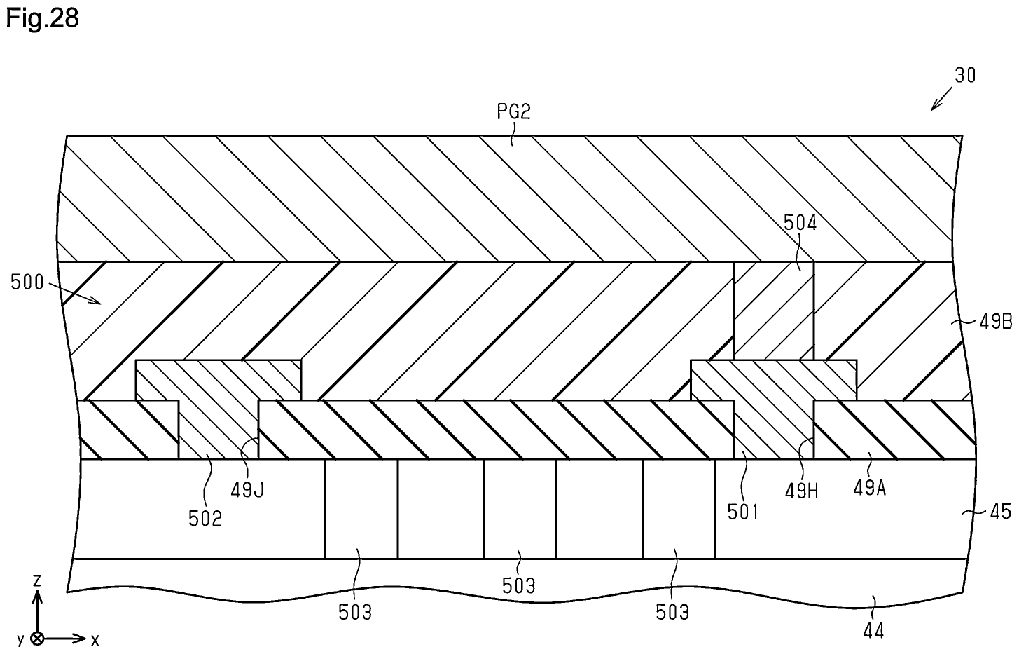

FIG. 28 shows the schematic cross-sectional structure of the protective diode 500 in the first modified example.

As shown in FIG. 28, for example, the protective diode 500 is arranged to overlap the pad PG2 in the second chip 30 in plan view.

The protective diode 500 includes the anode electrode 501, the cathode electrode 502, the drift layer 45 electrically connecting the anode electrode 501 and the cathode electrode 502, and a well region 503 differing in type of conductivity from the drift layer 45. In the shown example, the well region 503 is a p-type semiconductor region. The anode electrode 501 is electrically connected to the pad PG2 by, for example, a via 504. The anode electrode 501 and the cathode electrode 502 may be formed from, for example, any conductive material including Cu, Al, an AlCu alloy, W, Ti, or TiN.

The anode electrode 501 and the cathode electrode 502 are separated from each other in the insulation film 49A. More specifically, two openings 49H and 49J are separated from each other and are formed in the insulation film 49A to expose the drift layer 45. The anode electrode 501 fills the opening 49H and extends out to an edge extending around the opening 49H. The cathode electrode 502 fills the opening 49J and extends out to an edge extending around the opening 49J. The portion of the anode electrode 501 extending out of the opening 49H and the portion of the cathode electrode 502 extending out of the opening 49J are covered by the intermediate insulation film 49B.

Instead of the protective diode 500, a shunt resistor may be used. The shunt resistor is configured to inhibit application of a voltage higher than the gate-source rated voltage to the gate electrode 41G (refer to FIG. 27) of the clamp transistor 41. With this configuration, the gate-source voltage of the clamp transistor 41 is less likely to increase excessively.

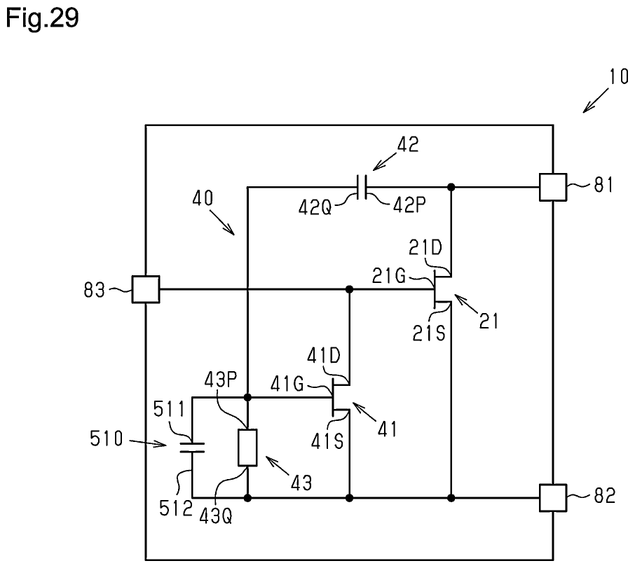

FIG. 29 shows the circuit configuration of the active clamp circuit 40 in the second modified example.

As shown in FIG. 29, in the second modified example, the active clamp circuit 40 further includes a capacitor 510 connected between the source electrode 41S and the gate electrode 41G of the clamp transistor 41. The capacitor 510 includes a first electrode 511 and a second electrode 512. The first electrode 511 is electrically connected to the gate electrode 41G of the clamp transistor 41 and the first terminal 43P of the pull-down resistor 43. The second electrode 512 is electrically connected to the source electrode 41S of the clamp transistor 41 and the second terminal 43Q of the pull-down resistor 43.

The capacitor 510 is configured to inhibit application of a voltage higher than the gate-source rated voltage to the gate electrode 41G of the clamp transistor 41. Thus, the gate-source voltage of the clamp transistor 41 is less likely to increase excessively.

The capacitor 510 may be formed in the same manner as the clamp capacitor 42. In the first embodiment, for example, the capacitor 510 may be arranged to overlap the gate pad PG1 of the second chip 30. In the second to fourth embodiments, in plan view, the capacitor 510 may be arranged at a position differing from the clamp transistor 41, the clamp capacitor 42, and the pull-down resistor 43 in plan view.

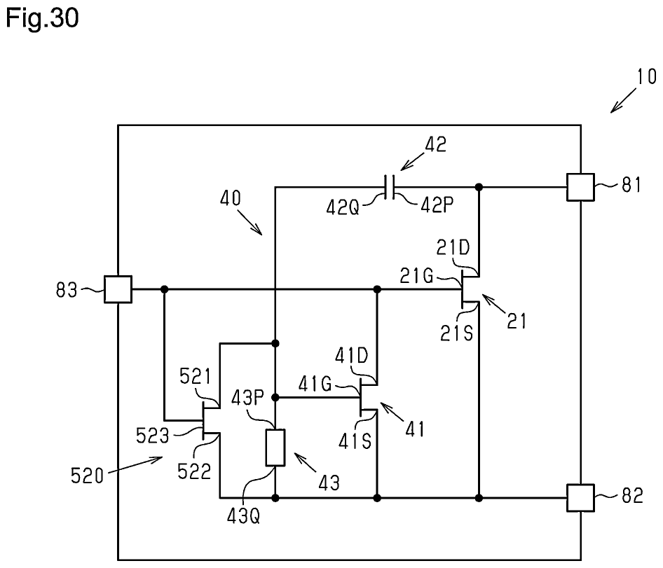

FIG. 30 shows the circuit configuration of the active clamp circuit 40 in the third modified example.

As shown in FIG. 30, in the third modified example, the active clamp circuit 40 further includes a protective transistor 520 that inhibits erroneous activation of the clamp transistor 41. The protective transistor 520 includes a drain electrode 521, a source electrode 522, and a gate electrode 523. The protective transistor 520 is connected between the source electrode 41S and the gate electrode 41G of the clamp transistor 41. More specifically, the drain electrode 521 of the protective transistor 520 is connected to the gate electrode 41G of the clamp transistor 41, and the source electrode 522 of the protective transistor 520 is connected to the source electrode 41S of the clamp transistor 41. The gate electrode 523 of the protective transistor 520 is connected to the gate terminal 83. The protective transistor 520 is a normally-off transistor in the same manner as the main transistor 21.

When the main transistor 21 is in an activation state, the protective transistor 520 is in an activation state. The protective transistor 520 connects the gate electrode 41G of the clamp transistor 41 and the source electrode 41S of the clamp transistor 41. Thus, when the main transistor 21 is in an activation state, the protective transistor 520 ensures deactivation of the clamp transistor 41. This avoids a situation in which the main transistor 21 is turned off at an unintended timing even when noise or the like is applied to an interconnect connected to the gate electrode 41G the clamp transistor 41.

When the main transistor 21 is in a deactivation state, the protective transistor 520 is in a deactivation state. This allows the clamp transistor 41 to be activated in accordance with the drain-source voltage of the main transistor 21. Thus, as described in the first embodiment, the clamp transistor 41 limits an increase in the gate-source voltage of the main transistor 21.

In at least one of the first modified example and the second modified example, the active clamp circuit 40 may include the protective transistor 520 of the third modified example. With this configuration, while the clamp transistor 41 is protected when the main transistor 21 is in a deactivation state, erroneous activation of the clamp transistor 41 is inhibited when the main transistor 21 is in an activation state.

In the fourth embodiment, at least a portion of the active clamp circuit 40 may be formed on the third chip 310. More specifically, a portion of the active clamp circuit 40 may be formed on the second chip 30, and elements of the active clamp circuit 40 that are not formed on the second chip 30 may be formed on the third chip 310.

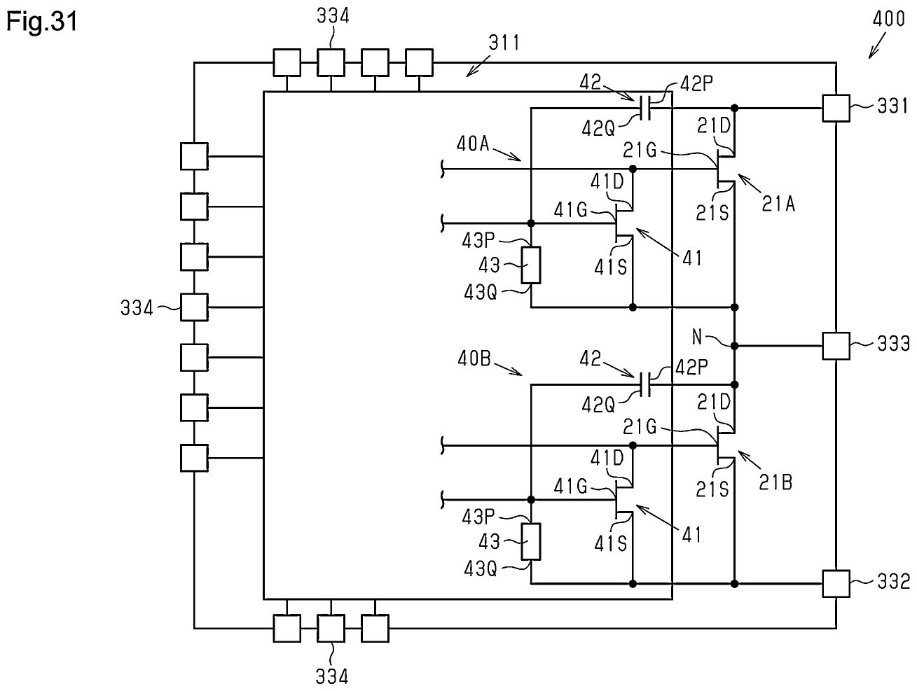

The active clamp circuits 40A and 40B may be entirely formed on the third chip 310. In this case, for example, as shown in FIG. 31, the active clamp circuit 40 may be formed at the output side of the driver circuit 311 of the third chip 310. In an example, the driver circuit 311 includes a push-pull circuit (not shown) configured to transmit a gate signal to the gate of the main transistor 21. The active clamp circuit 40 is formed between the push-pull circuit and an output terminal (electrode pad 312) of the driver circuit 311. When the active clamp circuit 40 is entirely formed on the third chip 310, the second chip 30 may be omitted from the semiconductor unit 400.

### Modified Examples of Semiconductor Module

In the first to third embodiments, the number of first chips 20 and second chips 30 may be changed in any manner. The semiconductor modules 10, 100, and 200 may include multiple first chips 20. The semiconductor modules 10, 100, and 200 may include multiple second chips 30. The semiconductor modules 10, 100, and 200 may include multiple first chips 20 and multiple second chips 30. When the semiconductor modules 10, 100, and 200 include multiple first chips 20 and multiple second chips 30, for example, the first chips 20 and the second chips 30 are equal in number.

In the second and third embodiments, the position of the second chip 30 with respect to the first chip 20 may be changed in any manner. In an example, the second chip 30 may be separated from the first chip 20 in the x-direction. In this case, as viewed in the x-direction, the second chip 30 is arranged to overlap the first chip 20.

In each embodiment, the first chip 20 and the second chip 30 are electrically connected to each other by a metal plate or an interconnect layer formed of a plating layer. However, the electrical connection structure of the first chip 20 and the second chip 30 is not limited to this. In an example, the first chip 20 and the second chip 30 may be electrically connected to each other by wires.

### Modified Examples of Semiconductor Unit

In the fourth embodiment, the number of third chips 310 may be changed in any manner. In an example, the number of third chips 310 may be changed in accordance with the number of first chips 20. In an example, in the fourth embodiment, since the number of first chips 20A and 20B is two, the number of third chips 310 may be two.

In the fourth embodiment, the arrangement of the second chips 30A and 30B may be changed in any manner. In an example, the second chips 30A and 30B may be arranged between the first chip 20A and the first chip 20B in the x-direction. In this case, the second chips 30A and 30B may be aligned with each other in the x-direction and separated from each other in the y-direction. In an example, the second chips 30A and 30B may be separately arranged at opposite sides of the third chip 310 in the x-direction.

In the fourth embodiment, the third chip 310, the first chips 20A and 20B, and the second chips 30A and 30B are electrically connected to each other by the interconnect layer formed of a plating layer. However, the electrical connection structure of the third chip 310, the first chips 20A and 20B, and the second chips 30A and 30B are not limited to this. In an example, the third chip 310, the first chips 20A and 20B, and the second chips 30A and 30B may be electrically connected to each other by wires.

In the fourth embodiment, the number of second chips 30 may be changed in any manner. In an example, a single second chip 30 may be used. In this case, the second chip 30 includes an active clamp circuit 40 electrically connected to the main transistor 21 of the first chip 20A and an active clamp circuit 40 electrically connected to the main transistor 21 of the first chip 20B. That is, the second chip 30 may include multiples active clamp circuits 40.

The semiconductor unit may include the semiconductor modules 10, 100, and 200 of the first to third embodiments and the third chip 310. The third chip 310 is encapsulated by the encapsulation resins 60 and 110 of the semiconductor modules 10, 100, and 200.

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily have to be the vertical direction and does not necessarily have to be fully aligned with the vertical direction. In the structures according to the present disclosure, “upward” and “downward” in the z-direction as referred to in the present description are not limited to “upward” and “downward” in the vertical direction. In an example, the x-direction may be aligned with the vertical direction. In another example, the y-direction may be aligned with the vertical direction.

In this specification, “at least one of A and B” should be understood to mean “only A, only B, or both A and B.”

### CLAUSES

The technical aspects that are understood from the embodiment and the modified examples will be described below. To facilitate understanding without intention to limit, the reference signs of the elements in the embodiments are given to the corresponding elements in the clause with parentheses. The reference signs are used as examples to facilitate understanding, and the components in each clause are not limited to those components given with the reference signs.

### [Clause 1]

A semiconductor module (10), including:
a first chip (20) including a main transistor (21) including a main drift layer (24);
a second chip (30) including at least part of an active clamp circuit (40) including a sub transistor (41) configured to be activated based on a rise of drain-source voltage of the main transistor (21);
a connection member (50) electrically connecting the main transistor (21) and the active clamp circuit (40);
an encapsulation resin (60) encapsulating the first chip (20), the second chip (30), and the connection member (50),
in which the sub transistor (41) includes a sub drift layer (45) composed of a material that differs from a material composing the main drift layer (24).

### [Clause 2]

The semiconductor module according to clause 1, in which
the main transistor (21) is a GaN transistor in which the main drift layer (24) is composed of GaN, and
the sub transistor (41) is a Si transistor in which the sub drift layer (45) is composed of Si.

### [Clause 3]

The semiconductor module according to clause 1 or 2, in which the main transistor (21) includes a drain electrode (21D), a source electrode (21S), and a gate electrode (21G), the semiconductor module, including:
a drain terminal (81) electrically connected to the drain electrode (21D);
a source terminal (82) electrically connected to the source electrode (21S); and
a gate terminal (83) electrically connected to the gate electrode (21G).

### [Clause 4]

The semiconductor module according to any one of clauses 1 to 3, in which
the sub transistor (41) includes a drain electrode (41D), a source electrode (41S), and a gate electrode (41G),
the source electrode (41S) of the sub transistor (41) is connected to a source electrode (21S) of the main transistor (21),
the drain electrode (41D) of the sub transistor (41) is connected to a gate electrode (21G) of the main transistor (21), and
the active clamp circuit (40) includes
   a pull-down resistor (43) connected between the source electrode (41S) and the gate electrode (41G) of the sub transistor (41), and
   a clamp capacitor (42) connected between a drain electrode (21D) of the main transistor (21) and the gate electrode (41G) of the sub transistor (41).

### [Clause 5]

The semiconductor module according to clause 4, in which
the first chip (20) does not include the active clamp circuit (40) and includes the main transistor (21), and
the second chip (30) includes the sub transistor (41), the pull-down resistor (43), and the clamp capacitor (42).

### [Clause 6]

The semiconductor module according to clause 5, in which the sub transistor (41), the pull-down resistor (43), and the clamp capacitor (42) are electrically connected to each other in the second chip (30).

### [Clause 7]

The semiconductor module according to any one of clauses 4 to 6, in which
the first chip (20) includes
   a drain pad (PD1) electrically connected to the drain electrode (21D) of the main transistor (21), and
   a source pad (PS1) electrically connected to the source electrode (21S) of the main transistor (21),
as viewed in a thickness-wise direction (z-direction) of the main drift layer (24), the drain pad (PD1) and the source pad (PS1) are arranged separately from each other in a first direction, and
as viewed in the thickness-wise direction (z-direction) of the main drift layer (24), the first chip (20) and the second chip (30) are arranged separately from each other in a second direction orthogonal to the first direction.

### [Clause 8]

The semiconductor module according to any one of clauses 4 to 7, in which
the second chip (30) includes a semiconductor substrate (44) supporting the sub drift layer (45),
a source region (48) is formed on a front surface of the sub drift layer (45) and electrically connected to the source electrode (41S) of the sub transistor (41), and
the drain electrode (41D) of the sub transistor (41) is formed on a back surface of the semiconductor substrate (44) located at a side opposite from the sub drift layer (45).

### [Clause 9]

The semiconductor module according to any one of clauses 4 to 7, in which
a drain region (46B) electrically connected to the drain electrode (41D) of the sub transistor (41) and a source region (48) electrically connected to the source electrode (41S) of the sub transistor (41) are separately arranged on a front surface of the sub drift layer (45).

### [Clause 10]

The semiconductor module according to any one of clauses 4 to 9, in which
the second chip (30) includes a pad (PG2) connected to the gate electrode (41G) of the sub transistor (41) through the pull-down resistor (43), and
as viewed in a thickness-wise direction (z-direction) of the sub drift layer (45), at least one of the pull-down resistor (43) and the clamp capacitor (42) is formed at a position overlapping the pad (PG2) and located closer to the sub drift layer (45) than the pad (PG2) is.

### [Clause 11]

The semiconductor module according to any one of clauses 4 to 9, in which the connection member (50) includes
a first connection member (51) electrically connecting the source electrode (21S) of the main transistor (21) to the source electrode (41S) and the gate electrode (41G) of the sub transistor (41),
a second connection member (52) electrically connecting the clamp capacitor (42) to the drain electrode (21D) of the main transistor (21), and
a third connection member (53) electrically connecting the gate electrode (21G) of the main transistor (21) and the drain electrode (41D) of the sub transistor (41).

### [Clause 12]

The semiconductor module according to clause 11, in which the first connection member (51), the second connection member (52), and the third connection member (53) are each formed of a metal plate.

### [Clause 13]

The semiconductor module according to clause 11, in which the first connection member (51), the second connection member (52), and the third connection member (53) are each formed of a metal plating.

### [Clause 14]

The semiconductor module according to any one of clauses 11 to 13, in which
the second chip (30) includes a capacitor pad (PCA) electrically connected to the clamp capacitor (42), and the second connection member (52) is bonded to the capacitor pad (PCA).

### [Clause 15]

The semiconductor module according to any one of clauses 1 to 14, in which
the first chip (20A, 20B) includes first chips arranged separately from each other, and
as viewed in a thickness-wise direction (z-direction) of the encapsulation resin (350), the second chip (30A, 30B) is separated from the first chips (20A, 20B) in a direction orthogonal to an arrangement direction of the first chips (20A, 20B).

### [Clause 16]

The semiconductor module according to clause 15, in which the second chip (30A, 30B) includes second chips arranged separately from each other in the arrangement direction of the first chips (20A, 20B).

### [Clause 17]

A semiconductor unit (400), including:
the semiconductor module (300) according to any one of clauses 1 to 16;
a third chip (310) arranged in the encapsulation resin (350) separately from the first chip (20) and the second chip (30) and including a driver circuit (311) configured to drive the main transistor (21); and
a control connection member (324, 325) electrically connecting the third chip (310) to the first chip (20) and the second chip (30).

### [Clause 18]

The semiconductor unit according to clause 17, in which
the main transistor (21) and the sub transistor (41) each include a drain electrode (21D, 41D), a source electrode (21S, 41S) and a gate electrode (21G, 41G), and
the control connection member (324, 325) electrically connects the driver circuit (311), the drain electrode (41D) of the sub transistor (41), and the gate electrode (21G) of the main transistor (21).

### [Clause 19]

The semiconductor module according to any one of clauses 2 to 14, further including:
a capacitor (510) connected between a source electrode (41S) and a gate electrode (41G) of the sub transistor (41).

### [Clause 20]

The semiconductor module according to any one of clauses 2 to 14, further including:
a protective diode (500) including an anode electrode (501) electrically connected to a source electrode (41S) of the sub transistor (41) and a cathode electrode (502) electrically connected to a gate electrode (41G) of the sub transistor (41).

### [Clause 21]

The semiconductor module according to any one of clauses 2 to 14, 20, and 21, further including:
a protective transistor (520) connected between a source electrode (41S) and a gate electrode (41G) of the sub transistor (41) and including a gate electrode (523) electrically connected to a gate electrode (21G) of the main transistor (21).

### [Clause 22]

The semiconductor module according to any one of clauses 4 to 14, in which
the second chip (30) includes a semiconductor substrate (44), and
the clamp capacitor (42) includes
   a first electrode (42P) and a second terminal (42Q) separately arranged on the semiconductor substrate (44), and
   a dielectric layer (49A) arranged on the semiconductor substrate (44) and sandwiched between the first electrode (42P) and the second terminal (42Q).

### [Clause 23]

The semiconductor module according to any one of clauses 4 to 14, further including:
a connection path (43A) electrically connecting the drain electrode (41D) of the sub transistor (41) and the source electrode (41S) of the sub transistor (41), in which
the connection path (43A) includes a serpentine portion, and
the pull-down resistor (43) includes a resistance component of the serpentine portion.

### [Clause 24]

The semiconductor module according to any one of clauses 4 to 14, in which
the second chip (30) includes a semiconductor substrate (44),
the pull-down resistor (43) includes
   a first terminal (43P),
   a second terminal (43Q), and
   a plate-shaped resistor part (43R) formed on the semiconductor substrate (44) and having a greater resistance than the first terminal (43P) and the second terminal (43Q), and
the first terminal (43P) and the second terminal (43Q) are arranged on the resistor part (43R) and are electrically connected to the resistor part (43R).

### [Clause 25]

The semiconductor module according to any one of clauses 4 to 14, in which the pull-down resistor (43) is configured by a normally-on transistor and includes an on-resistance of the normally-on transistor.

### [Clause 26]

The semiconductor module according to any one of clauses 1 to 16 and 19 to 24, in which the sub transistor (41) is configured to be turned on earlier than the main transistor (21) in response to a rise of drain-source voltage of the main transistor (21).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

1. A semiconductor module, comprising:
a first chip including a main transistor including a main drift layer;
a second chip including at least part of an active clamp circuit including a sub transistor configured to be activated based on a rise of drain-source voltage of the main transistor;
a connection member electrically connecting the main transistor and the active clamp circuit;
an encapsulation resin encapsulating the first chip, the second chip, and the connection member,
wherein the sub transistor includes a sub drift layer composed of a material that differs from a material composing the main drift layer.

2. The semiconductor module according to claim 1, wherein
the main transistor is a GaN transistor in which the main drift layer is composed of GaN, and
the sub transistor is a Si transistor in which the sub drift layer is composed of Si.

3. The semiconductor module according to claim 1, wherein the main transistor includes a drain electrode, a source electrode, and a gate electrode, the semiconductor module further comprising:
a drain terminal electrically connected to the drain electrode;
a source terminal electrically connected to the source electrode; and
a gate terminal electrically connected to the gate electrode.

4. The semiconductor module according to claim 1, wherein
the sub transistor includes a drain electrode, a source electrode, and a gate electrode,
the source electrode of the sub transistor is connected to a source electrode of the main transistor,
the drain electrode of the sub transistor is connected to a gate electrode of the main transistor, and
the active clamp circuit includes
a pull-down resistor connected between the source electrode and the gate electrode of the sub transistor, and
a clamp capacitor connected between a drain electrode of the main transistor and the gate electrode of the sub transistor.

5. The semiconductor module according to claim 4, wherein
the first chip does not include the active clamp circuit and includes the main transistor, and
the second chip includes the sub transistor, the pull-down resistor, and the clamp capacitor.

6. The semiconductor module according to claim 5, wherein the sub transistor, the pull-down resistor, and the clamp capacitor are electrically connected to each other in the second chip.

7. The semiconductor module according to claim 4, wherein
the first chip includes
a drain pad electrically connected to the drain electrode of the main transistor, and
a source pad electrically connected to the source electrode of the main transistor,
as viewed in a thickness-wise direction of the main drift layer, the drain pad and the source pad are arranged separately from each other in a first direction, and
as viewed in the thickness-wise direction of the main drift layer, the first chip and the second chip are arranged separately from each other in a second direction orthogonal to the first direction.

8. The semiconductor module according to claim 4, wherein
the second chip includes a semiconductor substrate supporting the sub drift layer,
a source region is formed on a front surface of the sub drift layer and electrically connected to the source electrode of the sub transistor, and
the drain electrode of the sub transistor is formed on a back surface of the semiconductor substrate located at a side opposite from the sub drift layer.

9. The semiconductor module according to claim 4, wherein
a drain region electrically connected to the drain electrode of the sub transistor and a source region electrically connected to the source electrode of the sub transistor are separately arranged on a front surface of the sub drift layer.

10. The semiconductor module according to claim 4, wherein
the second chip includes a pad connected to the gate electrode of the sub transistor through the pull-down resistor, and
as viewed in a thickness-wise direction of the sub drift layer, at least one of the pull-down resistor and the clamp capacitor is formed at a position overlapping the pad and located closer to the sub drift layer than the pad is.

11. The semiconductor module according to claim 4, wherein the connection member includes
a first connection member electrically connecting the source electrode of the main transistor to the source electrode and the gate electrode of the sub transistor,
a second connection member electrically connecting the clamp capacitor to the drain electrode of the main transistor, and
a third connection member electrically connecting the gate electrode of the main transistor and the drain electrode of the sub transistor.

12. The semiconductor module according to claim 11, wherein the first connection member, the second connection member, and the third connection member are each formed of a metal plate.

13. The semiconductor module according to claim 11, wherein the first connection member, the second connection member, and the third connection member are each formed of a metal plating.

14. The semiconductor module according to claim 11, wherein
the second chip includes a capacitor pad electrically connected to the clamp capacitor, and
the second connection member is bonded to the capacitor pad.

15. The semiconductor module according to claim 1, wherein
the first chip includes first chips arranged separately from each other, and
as viewed in a thickness-wise direction of the encapsulation resin, the second chip is separated from the first chips in a direction orthogonal to an arrangement direction of the first chips.

16. The semiconductor module according to claim 15, wherein the second chip includes second chips arranged separately from each other in the arrangement direction of the first chips.

17. A semiconductor unit, comprising:
the semiconductor module according to claim 1;
a third chip arranged in the encapsulation resin separately from the first chip and the second chip and including a driver circuit configured to drive the main transistor; and
a control connection member electrically connecting the third chip to the first chip and the second chip.

18. The semiconductor unit according to claim 17, wherein
the main transistor and the sub transistor each include a drain electrode, a source electrode and a gate electrode, and
the control connection member connects the driver circuit, the drain electrode of the sub transistor, and the gate electrode of the main transistor.
